(19) United States
(12) Patent Application Publication
(10) Pub. No.: US 2023/0364887 A1
(43) Pub. Date: Nov. 16, 2023

(54) POLYMER FILM, LAMINATE, AND METHOD FOR MANUFACTURING SAME

(71) Applicant: FUJIFILM Corporation, Tokyo (JP)

(72) Inventors: Yasuyuki Sasada, Shizuoka (JP); Naoyuki Morooka, Shizuoka (JP)

(73) Assignee: FUJIFILM Corporation, Tokyo (JP)

(21) Appl. No.: 18/358,928

(22) Filed: Jul. 25, 2023

Related U.S. Application Data
(63) Continuation of application No. PCT/JP2022/003167, filed on Jan. 27, 2022.

(30) Foreign Application Priority Data
Jan. 29, 2021 (JP) 2021-013762

(51) Int. Cl. B32B 15/09; C08L 67/04; C08L 77/12; H05K 1/03; B32B 7/022; B32B 7/025

(52) U.S. Cl. CPC B32B 15/09; C08L 67/04; C08L 77/12; H05K 1/0373; B32B 7/022; B32B 7/025; C08L 2203/16; C08L 2205/12; C08L 2203/206; H05K 2201/0141; H05K 1/0393; B32B 2457/08

(57) ABSTRACT

Provided are a polymer film including a layer A and a layer B on at least one surface of the layer A, in which the layer A contains a polymer having a dielectric loss tangent of 0.01 or less or at least one polymer A selected from the group consisting of a liquid crystal polymer, a fluorine-based polymer, a polymerized substance of a compound which has a cyclic aliphatic hydrocarbon group and a group having an ethylenically unsaturated bond, a polyphenylene ether, and an aromatic polyether ketone, the layer B contains an additive, and the layer B has an inflection point in a change in elastic modulus due to a change in temperature or a change in deformation rate, or has a reduced elastic modulus under pressurization; a laminate using the polymer film; and a method for manufacturing the same.

### CROSS-REFERENCE TO RELATED APPLICATIONS

This application is a continuation application of International Application No. PCT/JP2022/003167, filed Jan. 27, 2022, the disclosure of which is incorporated herein by reference in its entirety. Further, this application claims priority from Japanese Patent Application No. 2021-013762, filed Jan. 29, 2021, the disclosure of which is incorporated herein by reference in its entirety.

### BACKGROUND OF THE INVENTION

### 1. Field of the Invention

The present disclosure relates to a polymer film, a laminate, and a method for manufacturing the same.

### 2. Description of the Related Art

In recent years, frequencies used in a communication equipment tend to be extremely high. In order to suppress transmission loss in a high frequency band, insulating materials used in a circuit board are required to have a lowered relative permittivity and a lowered dielectric loss tangent.

In the related art, polyimide is commonly used as the insulating material used in the circuit board, a liquid crystal polymer which has high heat resistance and low water absorption and is small in loss in the high frequency band has been attracted.

As a polymer film in the related art, for example, JP2020-26474A discloses a liquid crystal polyester film that contains at least liquid crystal polyester, in which, in a case where a first alignment degree is set to an alignment degree with respect to a first direction parallel to a main surface of the liquid crystal polyester film, and a second alignment degree is set to an alignment degree with respect to a second direction parallel to the main surface and perpendicular to the first direction, a first alignment degree/second alignment degree that is a ratio of the first alignment degree and the second alignment degree is equal to or greater than 0.95 and equal to or less than 1.04, and a third alignment degree of the liquid crystal polyester that is measured by a wide angle X-ray scattering method in a direction parallel to the main surface is equal to or greater than 60.0%.

In addition, as a peelable laminated film in the related art, a film disclosed in JP2013-46992A is known.

JP2013-46992A discloses a peelable laminated film having a laminate including a layer A containing cellulose ester and a layer B containing a resin capable of solution film formation, which is different from the cellulose ester, in which an adhesive force between the layer A and the layer B is 5 N/cm or less.

### SUMMARY OF THE INVENTION

An object to be achieved by an embodiment of the present invention is to provide a polymer film effective for suppressing wiring distortion.

An object to be achieved by another embodiment of the present invention is to provide a laminate using the above-described polymer film, and a method for manufacturing the same.

The methods for achieving the above-described objects include the following aspects.
<1> A polymer film comprising:
a layer A; and
a layer B on at least one surface of the layer A,
in which the layer A contains a polymer having a dielectric loss tangent of 0.01 or less,
the layer B contains an additive, and
the layer B has an inflection point in a change in elastic modulus due to a change in temperature or a change in deformation rate, or has a reduced elastic modulus under pressurization.
<2> A polymer film comprising:
a layer A; and
a layer B on at least one surface of the layer A,
in which the layer A contains at least one polymer A selected from the group consisting of a liquid crystal polymer, a fluorine-based polymer, a polymerized substance of a compound which has a cyclic aliphatic hydrocarbon group and a group having an ethylenically unsaturated bond, a polyphenylene ether, and an aromatic polyether ketone,
the layer B contains an additive, and
the layer B has an inflection point in a change in elastic modulus due to a change in temperature or a change in deformation rate, or has a reduced elastic modulus under pressurization.
<3> A polymer film comprising:
a layer A; and
a layer B on at least one surface of the layer A,
in which the layer A contains a polymer having a dielectric loss tangent of 0.01 or less, and
the layer B contains an additive which is compatible with the polymer having a dielectric loss tangent of 0.01 or less at 25° C. and is to be phase-separable from the polymer having a dielectric loss tangent of 0.01 or less by heating.
<4> A polymer film comprising:
a layer A; and
a layer B on at least one surface of the layer A,
in which the layer A contains at least one polymer A selected from the group consisting of a liquid crystal polymer, a fluorine-based polymer, a polymerized substance of a compound which has a cyclic aliphatic hydrocarbon group and a group having an ethylenically unsaturated bond, a polyphenylene ether, and an aromatic polyether ketone, and
the layer B contains an additive which is compatible with the polymer A at 25° C. and is to be phase-separable from the polymer A by heating.
<5> A polymer film comprising:
a layer A; and
a layer B on at least one surface of the layer A,
in which the layer A contains a polymer having a dielectric loss tangent of 0.01 or less, and
the layer B contains an additive which is phase-separable from the polymer having a dielectric loss tangent of 0.01 or less at 25° C. and is to be compatible with the polymer having a dielectric loss tangent of 0.01 or less by heating.
<6> A polymer film comprising:
a layer A; and
a layer B on at least one surface of the layer A,
in which the layer A contains at least one polymer A selected from the group consisting of a liquid crystal polymer, a fluorine-based polymer, a polymerized substance of a compound which has a cyclic aliphatic hydrocarbon group and a group having an ethylenically unsaturated bond, a polyphenylene ether, and an aromatic polyether ketone, and
the layer B contains an additive which is phase-separable from the polymer A at 25° C. and is to be compatible with the polymer A by heating.
<7> The polymer film according to any one of <1> to <6>,
in which the layer B contains the polymer having a dielectric loss tangent of 0.01 or less.
<8> The polymer film according to any one of <1> to <7>,
in which an elastic modulus of the layer B at 160° C. is 1 GPa or less.
<9> The polymer film according to any one of <1> to <8>,
in which a melting point of the additive is 130° C. to 180° C.
<10> The polymer film according to any one of <1> to <9>,
in which an elastic modulus of the layer B at 300° C. is 1 GPa or less.
<11> The polymer film according to any one of <1> to <8>,
in which a melting point of the additive is 270° C. to 320° C.
<12> The polymer film according to any one of <1> to <11>,
in which an elastic modulus of the layer B at 160° C. is reduced under pressurization at 5 MPa.
<13> The polymer film according to <12>,
in which the additive is an additive which is compatible with the polymer having a dielectric loss tangent of 0.01 or less or the polymer A, and is to be phase-separable from the polymer having a dielectric loss tangent of 0.01 or less or the polymer A under pressurization at 5 MPa.
<14> The polymer film according to <12>,
in which the additive is an additive which is phase-separable from the polymer having a dielectric loss tangent of 0.01 or less or the polymer A, and is to be compatible in the polymer having a dielectric loss tangent of 0.01 or less or the polymer A under pressurization at 5 MPa.
<15> The polymer film according to any one of <1> to <14>,
in which the polymer having a dielectric loss tangent of 0.01 or less or the polymer A is a liquid crystal polymer.
<16> The polymer film according to any one of <1> to <15>,
in which a melting point Tm or a 5%-by-mass-loss temperature Td of the polymer having a dielectric loss tangent of 0.01 or less or the polymer A is 200° C. or higher.
<17> The polymer film according to any one of <1> to <16>,
in which the polymer having a dielectric loss tangent of 0.01 or less or the polymer A is a liquid crystal polymer having a structural unit represented by any of Formulae (1) to (3),

—O—Ar¹—CO— Formula (1)

—CO—Ar²—CO— Formula (2)

—X—Ar³—Y— Formula (3)
in Formulae (1) to (3), Ar¹ represents a phenylene group, a naphthylene group, or a biphenylylene group, Ar² and Ar³ each independently represent a phenylene group, a naphthylene group, a biphenylylene group, or a group represented by Formula (4), X and Y each independently represent an oxygen atom or an imino group, and hydrogen atoms in Ar¹ to Ar³ may be each independently substituted with a halogen atom, an alkyl group, or an aryl group,

—Ar⁴—Z—Ar⁵— Formula (4)
in Formula (4), Ar⁴ and Ar⁵ each independently represent a phenylene group or a naphthylene group, and Z represents an oxygen atom, a sulfur atom, a carbonyl group, a sulfonyl group, or an alkylene group.
<18> The polymer film according to any one of <1> to <17>, further comprising:
a layer C,
in which the layer B, the layer A, and the layer C are provided in this order, and
the layer C contains the additive.
<19> A laminate comprising:
the polymer film according to any one of <1> to <18>; and
a copper layer or a copper wire disposed on at least one surface of the polymer film.
<20> The laminate according to <19>,
in which a peel strength between the polymer film and the copper layer is 0.5 kN/m or more.
<21> A method for manufacturing a laminate, comprising:
a lamination step of laminating the polymer film according to any one of <1> to <18> with a copper layer or a copper wire at a temperature of (a melting point of the additive−30° C.) or higher and (the melting point+30° C.) or lower.
<22> A method for manufacturing a laminate, comprising:
a lamination step of laminating the polymer film according to any one of <1> to <18> with a copper layer or a copper wire at a pressure of (a pressure at which an elastic modulus of the layer B changes−5 MPa) or more and (the pressure at which the elastic modulus of the layer B changes+10 MPa) or less.
<23> A method for manufacturing a laminate, comprising:
a step of laminating the polymer film according to any one of <1> to <18> with a copper layer or a copper wire at a temperature of (a melting point of the additive−30° C.) or higher and (the melting point+30° C.) or lower and at a pressure of (a pressure at which an elastic modulus of the layer B changes−5 MPa) or more and (the pressure at which the elastic modulus of the layer B changes+10 MPa) or less.

According to the embodiment of the present invention, it is possible to provide a polymer film effective for suppressing wiring distortion.

Further, according to another embodiment of the present invention, it is possible to provide a laminate using the above-described polymer film and a method for manufacturing the same.

### DESCRIPTION OF THE PREFERRED EMBODIMENTS

Hereinafter, the contents of the present disclosure will be described in detail. The description of configuration requirements below is made based on representative embodiments of the present disclosure in some cases, but the present disclosure is not limited to such embodiments.

Further, in the present specification, a numerical range shown using “to” indicates a range including numerical values described before and after “to” as a lower limit and an upper limit.

In a numerical range described in a stepwise manner in the present disclosure, an upper limit or a lower limit described in one numerical range may be replaced with an upper limit or a lower limit in another numerical range described in a stepwise manner. Further, in a numerical range described in the present disclosure, an upper limit or a lower limit described in the numerical range may be replaced with a value described in an example.

Further, in a case where substitution or unsubstitution is not noted in regard to the notation of a “group” (atomic group) in the present specification, the “group” includes not only a group that does not have a substituent but also a group having a substituent. For example, the concept of an “alkyl group” includes not only an alkyl group that does not have a substituent (unsubstituted alkyl group) but also an alkyl group having a substituent (substituted alkyl group).

In the present specification, the concept of “(meth)acryl” includes both acryl and methacryl, and the concept of “(meth)acryloyl” includes both acryloyl and methacryloyl.

Further, the term “step” in the present specification indicates not only an independent step but also a step which cannot be clearly distinguished from other steps as long as the intended purpose of the step is achieved. Further, in the present disclosure, “% by mass” has the same definition as that for “% by weight”, and “part by mass” has the same definition as that for “part by weight”.

Furthermore, in the present disclosure, a combination of two or more preferred embodiments is a more preferred embodiment.

Further, the weight-average molecular weight (Mw) and the number-average molecular weight (Mn) in the present disclosure are molecular weights converted using polystyrene as a standard substance by performing detection with a gel permeation chromatography (GPC) analysis apparatus using TSKgel SuperHM-H (trade name, manufactured by Tosoh Corporation) column, a solvent of pentafluorophenol (PFP) and chloroform at a mass ratio of 1:2, and a differential refractometer, unless otherwise specified.

(Polymer Film)

A first embodiment of the polymer film according to the present disclosure includes a layer A and a layer B on at least one surface of the layer A, in which the layer A contains a polymer having a dielectric loss tangent of 0.01 or less, the layer B contains an additive, and the layer B has an inflection point in a change in elastic modulus due to a change in temperature or a change in deformation rate, or has a reduced elastic modulus under pressurization.

A second embodiment of the polymer film according to the present disclosure includes a layer A and a layer B on at least one surface of the layer A, in which the layer A contains at least one polymer A selected from the group consisting of a liquid crystal polymer, a fluorine-based polymer, a polymerized substance of a compound which has a cyclic aliphatic hydrocarbon group and a group having an ethylenically unsaturated bond, a polyphenylene ether, and an aromatic polyether ketone, the layer B contains an additive, and the layer B has an inflection point in a change in elastic modulus due to a change in temperature or a change in deformation rate, or has a reduced elastic modulus under pressurization.

A third embodiment of the polymer film according to the present disclosure includes a layer A and a layer B on at least one surface of the layer A, in which the layer A contains a polymer having a dielectric loss tangent of 0.01 or less, and the layer B contains an additive which is compatible with the polymer having a dielectric loss tangent of 0.01 or less at 25° C. and is to be phase-separable from the polymer having a dielectric loss tangent of 0.01 or less by heating.

A fourth embodiment of the polymer film according to the present disclosure includes a layer A and a layer B on at least one surface of the layer A, in which the layer A contains at least one polymer A selected from the group consisting of a liquid crystal polymer, a fluorine-based polymer, a polymerized substance of a compound which has a cyclic aliphatic hydrocarbon group and a group having an ethylenically unsaturated bond, a polyphenylene ether, and an aromatic polyether ketone, and the layer B contains an additive which is compatible with the polymer A at 25° C. and is to be phase-separable from the polymer A by heating.

A fifth embodiment of the polymer film according to the present disclosure includes a layer A and a layer B on at least one surface of the layer A, in which the layer A contains a polymer having a dielectric loss tangent of 0.01 or less, and the layer B contains an additive which is phase-separable from the polymer having a dielectric loss tangent of 0.01 or less at 25° C. and is to be compatible with the polymer having a dielectric loss tangent of 0.01 or less by heating.

A sixth embodiment of the polymer film according to the present disclosure includes a layer A and a layer B on at least one surface of the layer A, in which the layer A contains at least one polymer A selected from the group consisting of a liquid crystal polymer, a fluorine-based polymer, a polymerized substance of a compound which has a cyclic aliphatic hydrocarbon group and a group having an ethylenically unsaturated bond, a polyphenylene ether, and an aromatic polyether ketone, and the layer B contains an additive which is phase-separable from the polymer A at 25° C. and is to be compatible with the polymer A by heating.

In the present specification, the expression “polymer film according to the embodiment of the present disclosure” or “polymer film” denotes all of the above-described first to sixth embodiments, unless otherwise specified.

The present inventor has found that, in a case where a polymer film in the related art is laminated on a wiring line (particularly, a metal wire), the wiring line may be distorted due to stress at the time of laminating.

As a result of intensive research conducted by the present inventor, it has been found that, with the above-described configuration, it is possible to provide a polymer film which is excellent in wiring distortion suppression property in a case of laminating a wiring line.

The detailed mechanism for obtaining the above-described effects is not clear, but assumed as follows.

Since the layer B has an inflection point in a change in elastic modulus due to a change in temperature or a change in deformation rate, the layer B has a reduced elastic modulus under pressurization, the layer B contains an additive which is compatible with the above-described polymer having a dielectric loss tangent of 0.01 or less or the above-described polymer A at 25° C. and is to be phase-separable from the above-described polymer having a dielectric loss tangent of 0.01 or less or the above-described polymer A by heating, or the layer B contains an additive which is phase-separable from the above-described polymer having a dielectric loss tangent of 0.01 or less or the above-described polymer A at 25° C. and is to be compatible with the above-described polymer having a dielectric loss tangent of 0.01 or less or the above-described polymer A by heating, it is presumed that the layer B in contact with the wiring line is rapidly softened under temperature, pressure, and deformation stress at the time of attaching the wiring line, so that the layer B is excellent in followability to surface shape (followability to irregularities), can reduce the stress at the time of laminating the wiring line, and can suppress the wiring distortion.

<Layer B>

The first or second embodiment of the polymer film according to the present disclosure includes a layer A and a layer B on at least one surface of the layer A, in which the layer B contains an additive and has an inflection point of a change in elastic modulus due to at least one change selected from the group consisting of a change in temperature, a change in pressure, and a change in deformation rate.

The third or fourth embodiment of the polymer film according to the present disclosure includes a layer A and a layer B on at least one surface of the layer A, in which the layer B contains an additive which is compatible with the above-described polymer having a dielectric loss tangent of 0.01 or less or the above-described polymer A at 25° C. and is to be phase-separable from the above-described polymer having a dielectric loss tangent of 0.01 or less or the above-described polymer A by heating.

The fifth or sixth embodiment of the polymer film according to the present disclosure includes a layer A and a layer B on at least one surface of the layer A, in which the layer B contains an additive which is phase-separable from the above-described polymer having a dielectric loss tangent of 0.01 or less or the above-described polymer A at 25° C. and is to be compatible with the above-described polymer having a dielectric loss tangent of 0.01 or less or the above-described polymer A by heating.

In addition, the layer B is preferably a surface layer (outermost layer).

—Inflection Point of Change in Elastic Modulus Due to Change in Temperature or Change in Deformation Rate and Decrease in Elastic Modulus Under Pressurization—

The above-described layer B in the first or second embodiment according to the polymer film according to the present disclosure has the inflection point in the change in elastic modulus due to the change in temperature or the change in deformation rate, or has a reduced elastic modulus under pressurization, and from the viewpoint of wiring distortion suppression property, it is preferable to have the inflection point in the change in elastic modulus due to the change in temperature or have a reduced elastic modulus under pressurization, and it is more preferable to have the inflection point in the change in elastic modulus due to the change in temperature.

From the viewpoint of wiring distortion suppression property, it is preferable that the above-described layer B in the third to sixth embodiments according to the polymer film according to the present disclosure has the inflection point in the change in elastic modulus due to the change in temperature or the change in deformation rate, or has a reduced elastic modulus under pressurization, it is more preferable to have the inflection point in the change in elastic modulus due to the change in temperature or have a reduced elastic modulus under pressurization, and it is particularly preferable to have the inflection point in the change in elastic modulus due to the change in temperature.

In addition, in a case where the polymer film according to the embodiment of the present disclosure has the inflection point in the change in elastic modulus due to the change in temperature, it is preferable that an elastic modulus of the above-described layer B at 25° C. is higher than an elastic modulus of the above-described layer B at a temperature higher than the above-described inflection point.

In a case where the polymer film according to the embodiment of the present disclosure has the inflection point in the change in elastic modulus due to the change in deformation rate, it is preferable that an elastic modulus of the above-described layer B in a case of not being deformed is higher than an elastic modulus of the above-described layer B at a deformation rate higher than the above-described inflection point.

In a case where the polymer film according to the embodiment of the present disclosure has a reduced elastic modulus under pressurization, it is preferable that an elastic modulus of the above-described layer B in a case of not being pressurized is higher than an elastic modulus of the above-described layer B at a pressure higher than the above-described inflection point.

A range of the above-described change in temperature is not particularly limited, but from the viewpoint of handleability of the polymer film and wiring distortion suppression property, it is preferably in a range of 50° C. to 400° C., more preferably in a range of 100° C. to 350° C., and particularly preferably in a range of 130° C. to 320° C.

A pressurization range under the above-described pressurization is not particularly limited, but from the viewpoint of handleability of the polymer film and wiring distortion suppression property, it is preferably in a range of 0.5 MPa to 20 MPa, more preferably in a range of 1 MPa to 10 MPa, and particularly preferably in a range of 2 MPa to 8 MPa.

In addition, a temperature under the above-described pressurization does not have to be, for example, 25° C. of normal temperature, and it is preferably 0° C. to 400° C., more preferably 50° C. to 400° C., still more preferably 100° C. to 350° C., and particularly preferably 130° C. to 320° C.

A range of the above-described change in deformation rate is not particularly limited, and from the viewpoint of handleability of the polymer film and wiring distortion suppression property, it is preferably in a range of 0.01 m/sec to 15,000 mm/sec, more preferably in a range of 0.1 m/sec to 2,000 mm/sec, and particularly preferably in a range of 1 m/sec to 500 mm/sec.

In addition, a temperature at which the change in deformation rate occurs does not have to be, for example, 25° C. of normal temperature, and it is preferably 0° C. to 400° C., more preferably 50° C. to 400° C., still more preferably 100° C. to 350° C., and particularly preferably 130° C. to 320° C.

As the elastic modulus due to the change in temperature or the change in deformation rate, using a dynamic mechanical analyzer (DMA), temperature dependence can be obtained by evaluating temperature dependence of a storage elastic modulus, and deformation rate dependence can be obtained by evaluating of frequency dependence of the storage elastic modulus.

The elastic modulus under pressurization can be calculated from an inclination of a curve at each pressure by measuring a distortion-stress curve by changing the pressurizing pressure using a micro-hardness meter.

—Additive—

The above-described layer B in the first or second embodiment according to the polymer film according to the present disclosure contains an additive.

The above-described layer B in the third or fourth embodiment of the polymer film according to the present disclosure contains an additive which is compatible with the above-described polymer having a dielectric loss tangent of 0.01 or less or the above-described polymer A at 25° C. and is to be phase-separable from the above-described polymer having a dielectric loss tangent of 0.01 or less or the above-described polymer A by heating.

The above-described layer B in the fifth or sixth embodiment of the polymer film according to the present disclosure contains an additive which is phase-separable from the above-described polymer having a dielectric loss tangent of 0.01 or less or the above-described polymer A at 25° C. and is to be compatible with the above-described polymer having a dielectric loss tangent of 0.01 or less or the above-described polymer A by heating.

The above-described additive in the first or second embodiment according to the polymer film according to the present disclosure is preferably an additive which is compatible with the above-described polymer having a dielectric loss tangent of 0.01 or less or the above-described polymer A at 25° C. and is to be phase-separable from the above-described polymer having a dielectric loss tangent of 0.01 or less or the above-described polymer A by heating, or an additive which is phase-separable from the above-described polymer having a dielectric loss tangent of 0.01 or less or the above-described polymer A at 25° C. and is to be compatible with the above-described polymer having a dielectric loss tangent of 0.01 or less or the above-described polymer A by heating; and more preferably an additive which is compatible with the above-described polymer having a dielectric loss tangent of 0.01 or less or the above-described polymer A at 25° C. and is to be phase-separable from the above-described polymer having a dielectric loss tangent of 0.01 or less or the above-described polymer A by heating.

It is preferable that the above-described layer B in the third or fourth embodiment of the polymer film according to the present disclosure does not contain the additive which is phase-separable from the above-described polymer having a dielectric loss tangent of 0.01 or less or the above-described polymer A at 25° C. and is to be compatible with the above-described polymer having a dielectric loss tangent of 0.01 or less or the above-described polymer A by heating.

It is preferable that the above-described layer B in the fifth or sixth embodiment of the polymer film according to the present disclosure does not contain the additive which is compatible with the above-described polymer having a dielectric loss tangent of 0.01 or less or the above-described polymer A at 25° C. and is to be phase-separable from the above-described polymer having a dielectric loss tangent of 0.01 or less or the above-described polymer A by heating.

The above-described additive in the polymer film according to the embodiment of the present disclosure is not particularly limited as long as it is an additive which allows the above-described layer B to have the inflection point of the elastic modulus due to at least one change selected from the group consisting of the change in temperature, the change in pressure, and the change in deformation rate, and from the viewpoint of wiring distortion suppression property, a melting point of the additive is preferably 100° C. to 400° C. and more preferably 130° C. to 320° C.

From the viewpoint of handleability and attachment at around 160° C., the melting point of the above-described additive is particularly preferably 130° C. to 180° C.

In addition, from the viewpoint of handleability and attachment at around 300° C., the melting point of the above-described additive is particularly preferably 270° C. to 320° C.

In a case where the above-described additive is a polymer, the above-described melting point means a softening point.

As the above-described additive in the polymer film according to the embodiment of the present disclosure, a polymer is preferable, and a thermoplastic resin is more preferable.

Examples of the above-described polymer include a liquid crystal polymer, a fluorine-based polymer, a polymerized substance of a compound which has a cyclic aliphatic hydrocarbon group and a group having an ethylenically unsaturated bond, polyether ether ketone, polyolefin, polyamide, polyester, polyphenylene sulfide, polyether ketone, polycarbonate, polyethersulfone, polyphenylene ether and a modified product thereof, and polyetherimide.

Among these, from the viewpoint of wiring distortion suppression property, a polymer having a glass transition temperature (Tg) or a phase transition temperature (for example, a melting point (Tm)) between room temperature to a laminating temperature in the lamination step described later is preferable, and polyester is more preferable.

In addition, preferred examples of the above-described additive in the polymer film according to the embodiment of the present disclosure also include phosphate ester compounds, phthalate ester compounds, trimellitate ester compounds, pyromellitic acid compounds, polyhydric alcohol ester compounds, glycolate compounds, citrate ester compounds, fatty acid ester compounds, carboxylate ester compounds, and polyester compounds.

Examples of the additive which is compatible with the above-described polymer having a dielectric loss tangent of 0.01 or less or the above-described polymer A at 25° C. and is to be phase-separable from the above-described polymer having a dielectric loss tangent of 0.01 or less or the above-described polymer A by heating include thermoplastic resins. Among these, polyester is preferable, polyester having a melting point of 100° C. to 400° C. is more preferable, and polyester having a melting point of 130° C. to 320° C. is particularly preferable.

Preferred examples of the additive which is phase-separable from the above-described polymer having a dielectric loss tangent of 0.01 or less or the above-described polymer A at 25° C. and is to be compatible with the above-described polymer having a dielectric loss tangent of 0.01 or less or the above-described polymer A by heating include phosphate ester compounds, phthalate ester compounds, trimellitate ester compounds, pyromellitic acid compounds, polyhydric alcohol ester compounds, glycolate compounds, citrate ester compounds, fatty acid ester compounds, carboxylate ester compounds, and polyesters.

Among these, from the viewpoint of wiring distortion suppression property, a compound having a melting point of 100° C. to 400° C. is more preferable, and a compound having a melting point of 130° C. to 320° C. is still more preferable.

In addition, from the viewpoint of wiring distortion suppression property and handleability of the polymer film, a phosphate ester compound, a trimellitate ester compound, a pyromellitic acid compound, or a polyhydric alcohol ester compound is preferable.

From the viewpoint of wiring distortion suppression property, handleability, and attachment at around 160° C., the elastic modulus of the above-described layer B at 160° C. is preferably 1 GPa or less, more preferably 0.8 GPa or less, and particularly preferably more than 0 GPa and 0.5 GPa or less.

In addition, from the viewpoint of wiring distortion suppression property, handleability, and attachment at around 300° C., the elastic modulus of the above-described layer B at 300° C. is preferably 1 GPa or less, more preferably 0.5 GPa or less, still more preferably 0.3 GPa or less, and particularly preferably more than 0 GPa and 0.2 GPa or less.

In addition, it is preferable that the elastic modulus of the above-described layer B at 160° C. is reduced under pressurization at 5 MPa.

In a case where the polymer film is under pressurization, preferably under pressurization at 5 MPa, the above-described additive is preferably an additive which is compatible with the above-described polymer having a dielectric loss tangent of 0.01 or less or the above-described polymer A, and is to be phase-separable from the above-described polymer having a dielectric loss tangent of 0.01 or less or the above-described polymer A under pressurization at 5 MPa.

In addition, in a case where the polymer film is under pressurization, preferably under pressurization at 5 MPa, the above-described additive is also preferably an additive which is phase-separable from the above-described polymer having a dielectric loss tangent of 0.01 or less or the above-described polymer A, and is to be compatible with the above-described polymer having a dielectric loss tangent of 0.01 or less or the above-described polymer A under pressurization at 5 MPa.

The above-described additive may be used alone or in combination of two or more kinds thereof.

From the viewpoint of wiring distortion suppression property, handleability of the polymer film, and storage stability, a content of the above-described additive in the above-described layer B is preferably 5% by mass to 90% by mass, more preferably 10% by mass to 80% by mass, still more preferably 20% by mass to 70% by mass, and particularly preferably 30% by mass to 70% by mass with respect to the total mass of the above-described layer B.

<Polymer Having Dielectric Loss Tangent of 0.01 or Less and Polymer A>

From the viewpoint of improving adhesiveness with the above-described layer A, the above-described layer B preferably contains a polymer having a dielectric loss tangent of 0.01 or less, more preferably contains the same kind of the polymer having a dielectric loss tangent of 0.01 or less as in the above-described layer A, and particularly preferably contains the same polymer having a dielectric loss tangent of 0.01 or less as in the above-described layer A. The same kind of polymer in the present disclosure means that the kind of resin, such as a polyester resin and a fluorine-based polymer, is the same.

From the viewpoint of improving adhesiveness with the above-described layer A, the above-described layer B preferably contains at least one polymer A selected from the group consisting of a liquid crystal polymer, a fluorine-based polymer, a polymerized substance of a compound which has a cyclic aliphatic hydrocarbon group and a group having an ethylenically unsaturated bond, a polyphenylene ether, and an aromatic polyether ketone, more preferably contains the same kind of the polymer A as in the above-described layer A, and particularly preferably contains the same polymer A as in the above-described layer A.

From the viewpoint of dielectric loss tangent of the polymer film and adhesiveness with the metal foil or the metal wire, the dielectric loss tangent of the polymer having a dielectric loss tangent of 0.01 or less or the above-described polymer A is preferably 0.005 or less, more preferably 0.004 or less, and particularly preferably more than 0 and 0.003 or less.

The dielectric loss tangent in the present disclosure is measured by the following method.

A dielectric constant is measured by a resonance perturbation method at a frequency of 10 GHz. A 10 GHz cavity resonator (CP531 manufactured by Kanto Electronics Application & Development Inc.) is connected to a network analyzer (“E8363B” manufactured by Agilent Technology), a sample (width: 2 mm×length: 80 mm) of the polymer film, each layer, or the polymer is inserted into the cavity resonator, and the dielectric constant and dielectric loss tangent of the polymer film, each layer, or the polymer are measured based on a change in resonance frequency for 96 hours before and after the insertion in an environment of a temperature of 25° C. and a humidity of 60% RH.

In a case where each layer of the polymer film is measured, an unnecessary layer may be scraped off with a razor or the like to produce an evaluation sample of only the target layer. In addition, in a case where it is difficult to take out the single film because the thickness of the layer is thin, a layer to be measured may be scraped off with a razor or the like, and the obtained powdery sample may be used. In the present disclosure, the measurement of the dielectric loss tangent of the polymer is carried out according to the above-described method for measuring a dielectric loss tangent by identifying or isolating a chemical structure of the polymer constituting each layer and using a powdered sample of the polymer to be measured.

A weight-average molecular weight Mw of the polymer having a dielectric loss tangent of 0.01 or less or the above-described polymer A is preferably 1,000 or more, more preferably 2,000 or more, and particularly preferably 5,000 or more. In addition, the weight-average molecular weight Mw of the polymer having a dielectric loss tangent of 0.01 or less or the above-described polymer A is preferably 1,000,000 or less, more preferably 300,000 or less, and particularly preferably less than 100,000.

From the viewpoint of dielectric loss tangent of the polymer film, adhesiveness with the metal foil or the metal wire, and heat resistance, a melting point Tm or a 5%-by-mass-loss temperature Td of the polymer having a dielectric loss tangent of 0.01 or less or the above-described polymer A is preferably 200° C. or higher, more preferably 250° C. or higher, still more preferably 280° C. or higher, and particularly preferably 300° C. or higher and 420° C. or lower.

The melting point Tm in the present disclosure is defined as a value measured by a differential scanning calorimetry (DSC) device. That is, 5 mg of a sample is put into a measurement pan of the DSC, and a peak temperature of an endothermic peak which appears in a case where the sample is heated from 30° C. at 10° C./min in a nitrogen stream is defined as the Tm of the film.

In addition, the 5%-by-mass-loss temperature Td in the present disclosure is measured with a thermogravimetric analysis (TGA) device. That is, a weight of the sample put into the measurement pan is defined as an initial value, and a temperature at which the weight is reduced by 5% by mass with respect to the initial value due to the heating is defined as the 5%-by-mass-loss temperature Td.

From the viewpoint of dielectric loss tangent of the polymer film, adhesiveness with the metal foil or the metal wire, and heat resistance, a glass transition temperature Tg of the polymer having a dielectric loss tangent of 0.01 or less or the above-described polymer A is preferably 150° C. or higher, more preferably 200° C. or higher, and particularly preferably 200° C. or higher and lower than 280° C.

The glass transition temperature Tg in the present disclosure is defined as a value measured by a differential scanning calorimetry (DSC) device.

In the present disclosure, the type of the polymer having a dielectric loss tangent of 0.01 or less is not particularly limited, and a known polymer can be used.

Examples of the polymer having a dielectric loss tangent of 0.01 or less include thermoplastic resins such as a liquid crystal polymer, a fluorine-based polymer, a polymerized substance of a compound which has a cyclic aliphatic hydrocarbon group and a group having an ethylenically unsaturated bond, aromatic polyether ketone, polyolefin, polyamide, polyester, polyphenylene sulfide, polyether ketone, polycarbonate, polyethersulfone, polyphenylene ether and a modified product thereof, and polyetherimide; elastomers such as a copolymer of glycidyl methacrylate and polyethylene; and thermosetting resins such as a phenol resin, an epoxy resin, a polyimide resin, and a cyanate resin.

Among these, from the viewpoint of dielectric loss tangent of the polymer film, adhesiveness with the metal foil or the metal wire, and heat resistance, at least one polymer selected from the group consisting of a liquid crystal polymer, a fluorine-based polymer, a polymerized substance of a compound which has a cyclic aliphatic hydrocarbon group and a group having an ethylenically unsaturated bond, and aromatic polyether ketone is preferable, and at least one polymer selected from the group consisting of a liquid crystal polymer and a fluorine-based polymer is more preferable, and a liquid crystal polymer is particularly preferable from the viewpoint of dielectric loss tangent of the polymer film; and from the viewpoint of heat resistance and mechanical strength, a fluorine-based polymer is particularly preferable.

In addition, as the above-described polymer A, from the viewpoint of dielectric loss tangent of the polymer film, adhesiveness with the metal foil or the metal wire, and heat resistance, at least one polymer selected from the group consisting of a liquid crystal polymer and a fluorine-based polymer is preferable. From the viewpoint of dielectric loss tangent of the polymer film, a liquid crystal polymer is more preferable, and from the viewpoint of heat resistance and mechanical strength, a fluorine-based polymer is more preferable.

—Liquid Crystal Polymer—

From the viewpoint of dielectric loss tangent of the polymer film, the polymer having a dielectric loss tangent of 0.01 or less or the above-described polymer A is preferably a liquid crystal polymer.

In the present disclosure, the type of the liquid crystal polymer used as the polymer having a dielectric loss tangent of 0.01 or less or the above-described polymer A is not particularly limited as long as the dielectric loss tangent thereof is 0.01 or less, and a known liquid crystal polymer can be used.

In addition, the liquid crystal polymer may be a thermotropic liquid crystal polymer which exhibits liquid crystallinity in a molten state, or may be a lyotropic liquid crystal polymer which exhibits liquid crystallinity in a solution state. In addition, in a case of the thermotropic liquid crystal, it is preferable that the liquid crystal is melted at a temperature of 450° C. or lower.

Examples of the liquid crystal polymer include a liquid crystal polyester, a liquid crystal polyester amide in which an amide bond is introduced into the liquid crystal polyester, a liquid crystal polyester ether in which an ether bond is introduced into the liquid crystal polyester, and a liquid crystal polyester carbonate in which a carbonate bond is introduced into the liquid crystal polyester.

In addition, as the liquid crystal polymer, from the viewpoint of liquid crystallinity and linear expansion coefficient, a polymer having an aromatic ring is preferable, an aromatic polyester or an aromatic polyester amide is more preferable, and an aromatic polyester amide is particularly preferable.

Further, the liquid crystal polymer may be a polymer in which an imide bond, a carbodiimide bond, a bond derived from an isocyanate, such as an isocyanurate bond, or the like is further introduced into the aromatic polyester or the aromatic polyester amide.

Further, it is preferable that the liquid crystal polymer is a wholly aromatic liquid crystal polymer formed of only an aromatic compound as a raw material monomer.

Examples of the liquid crystal polymer include the following liquid crystal polymers.
1) a liquid crystal polymer obtained by polycondensing (i) an aromatic hydroxycarboxylic acid, (ii) an aromatic dicarboxylic acid, and (iii) at least one compound selected from the group consisting of an aromatic diol, an aromatic hydroxyamine, and an aromatic diamine;
2) a liquid crystal polymer obtained by polycondensing a plurality of types of aromatic hydroxycarboxylic acids;
3) a liquid crystal polymer obtained by polycondensing (i) an aromatic dicarboxylic acid and (ii) at least one compound selected from the group consisting of an aromatic diol, an aromatic hydroxyamine, and an aromatic diamine;
4) a liquid crystal polymer obtained by polycondensing (i) polyester such as polyethylene terephthalate and (ii) an aromatic hydroxycarboxylic acid.

Here, the aromatic hydroxycarboxylic acid, the aromatic dicarboxylic acid, the aromatic diol, the aromatic hydroxyamine, and the aromatic diamine may be each independently replaced with a polycondensable derivative.

For example, the aromatic hydroxycarboxylic acid and the aromatic dicarboxylic acid can be replaced with aromatic hydroxycarboxylic acid ester and aromatic dicarboxylic acid ester, by converting a carboxy group into an alkoxycarbonyl group or an aryloxycarbonyl group.

The aromatic hydroxycarboxylic acid and the aromatic dicarboxylic acid can be replaced with aromatic hydroxycarboxylic acid halide and aromatic dicarboxylic acid halide, by converting a carboxy group into a haloformyl group.

The aromatic hydroxycarboxylic acid and the aromatic dicarboxylic acid can be replaced with aromatic hydroxycarboxylic acid anhydride and aromatic dicarboxylic acid anhydride, by converting a carboxy group into an acyloxycarbonyl group.

Examples of a polymerizable derivative of a compound having a hydroxy group, such as an aromatic hydroxycarboxylic acid, an aromatic diol, and an aromatic hydroxyamine, include a derivative (acylated product) obtained by acylating a hydroxy group and converting the acylated group into an acyloxy group.

For example, the aromatic hydroxycarboxylic acid, the aromatic diol, and the aromatic hydroxyamine can be each replaced with an acylated product by acylating a hydroxy group and converting the acylated group into an acyloxy group.

Examples of a polymerizable derivative of a compound having an amino group, such as an aromatic hydroxyamine or an aromatic diamine, include a derivative (acylated product) obtained by acylating an amino group and converting the acylated group to an acylamino group.

For example, the aromatic hydroxyamine and the aromatic diamine can be each replaced with an acylated product by acylating an amino group and converting the acylated group into an acylamino group.

From the viewpoint of liquid crystallinity, dielectric loss tangent of the polymer film, and adhesiveness with the metal foil or the metal wire, the liquid crystal polymer preferably has a structural unit represented by any of Formulae (1) to (3) (hereinafter, a structural unit represented by Formula (1) or the like may be referred to as a structural unit (1) or the like), more preferably has a structural unit represented by Formula (1), and particularly preferably has a structural unit represented by Formula (1), a structural unit represented by Formula (2), and a structural unit represented by Formula (3).

—O—Ar¹—CO— Formula (1)

—CO—Ar²—CO— Formula (2)

—X—Ar³—Y— Formula (3)

In Formulae (1) to (3), Ar¹ represents a phenylene group, a naphthylene group, or a biphenylylene group, Ar² and Ar³ each independently represent a phenylene group, a naphthylene group, a biphenylylene group, or a group represented by Formula (4), X and Y each independently represent an oxygen atom or an imino group, and hydrogen atoms in Ar¹ to Ar³ may be each independently substituted with a halogen atom, an alkyl group, or an aryl group.

—Ar⁴—Z—Ar⁵— Formula (4)

In Formula (4), Ar⁴ and Ar⁵ each independently represent a phenylene group or a naphthylene group, and Z represents an oxygen atom, a sulfur atom, a carbonyl group, a sulfonyl group, or an alkylene group.

Examples of the halogen atom include a fluorine atom, a chlorine atom, a bromine atom, and an iodine atom.

Examples of the alkyl group include a methyl group, an ethyl group, an n-propyl group, an isopropyl group, an n-butyl group, an isobutyl group, an s-butyl group, a t-butyl group, an n-hexyl group, a 2-ethylhexyl group, an n-octyl group, and an n-decyl group, and the number of carbon atoms thereof is preferably 1 to 10.

Examples of the aryl group include a phenyl group, an o-tolyl group, an m-tolyl group, a p-tolyl group, a 1-naphthyl group, and a 2-naphthyl group, and the number of carbon atoms thereof is preferably 6 to 20.

In a case where the hydrogen atom is substituted with these groups, the number thereof for each group independently represented by Ar¹, Ar², or Ar³ is preferably 2 or less and more preferably 1.

Examples of the alkylene group include a methylene group, a 1,1-ethanediyl group, a 1-methyl-1,1-ethanediyl group, a 1,1-butanediyl group, and a 2-ethyl-1,1-hexanediyl group, and the number of carbon atoms thereof is preferably 1 to 10.

The structural unit (1) is a structural unit derived from a predetermined aromatic hydroxycarboxylic acid.

As the structural unit (1), an aspect in which Ar¹ represents a p-phenylene group (structural unit derived from p-hydroxybenzoic acid), an aspect in which Ar¹ represents a 2,6-naphthylene group (structural unit derived from 6-hydroxy-2-naphthoic acid), or an aspect in which Ar¹ represents a 4,4′-biphenylylene group (structural unit derived from 4′-hydroxy-4-biphenylcarboxylic acid) is preferable.

The structural unit (2) is a structural unit derived from a predetermined aromatic dicarboxylic acid.

As the structural unit (2), an aspect in which Ar² represents a p-phenylene group (structural unit derived from terephthalic acid), an aspect in which Ar² represents an m-phenylene group (structural unit derived from isophthalic acid), an aspect in which Ar² represents a 2,6-naphthylene group (structural unit derived from 2,6-naphthalenedicarboxylic acid), or an aspect in which Ar² represents a diphenylether-4,4′-diyl group (structural unit derived from diphenylether-4,4′-dicarboxylic acid) is preferable.

The structural unit (3) is a structural unit derived from a predetermined aromatic diol, aromatic hydroxylamine, or aromatic diamine.

As the structural unit (3), an aspect in which Ar³ represents a p-phenylene group (structural unit derived from hydroquinone, p-aminophenol, or p-phenylenediamine), an aspect in which Ar³ represents an m-phenylene group (structural unit derived from isophthalic acid), or an aspect in which Ar³ represents a 4,4′-biphenylylene group (structural unit derived from 4,4′-dihydroxybiphenyl, 4-amino-4′-hydroxybiphenyl, or 4,4′-diaminobiphenyl) is preferable.

A content of the structural unit (1) is preferably 30% by mole or more, more preferably 30% to 80% by mole, still more preferably 30% to 60% by mole, and particularly preferably 30% to 40% by mole with respect to the total amount of all structural units (a value obtained by dividing the mass of each structural unit constituting the liquid crystal polymer by the formula weight of each structural unit to calculate an amount (mol) equivalent to the substance amount of each structural unit and adding up the amounts).

The content of the structural unit (2) is preferably 35% by mole or less, more preferably 10% by mole to 35% by mole, still more preferably 20% by mole to 35% by mole, and particularly preferably 30% by mole to 35% by mole with respect to the total amount of all structural units.

The content of the structural unit (3) is preferably 35% by mole or less, more preferably 10% by mole to 35% by mole, still more preferably 20% by mole to 35% by mole, and particularly preferably 30% by mole to 35% by mole with respect to the total amount of all structural units.

The heat resistance, the strength, and the rigidity are likely to be improved as the content of the structural unit (1) increases, but the solubility in a solvent is likely to be decreased in a case where the content thereof is extremely large.

A proportion of the content of the structural unit (2) to the content of the structural unit (3) is expressed as [content of structural unit (2)]/[content of structural unit (3)] (mol/mol), and is preferably 0.9/1 to 1/0.9, more preferably 0.95/1 to 1/0.95, and still more preferably 0.98/1 to 1/0.98.

The liquid crystal polymer may have two or more kinds of each of the structural units (1) to (3) independently. In addition, the liquid crystal polymer may have a structural unit other than the structural units (1) to (3), but the content thereof is preferably 10% by mole or less and more preferably 5% by mole or less with respect to the total amount of all the structural units.

From the viewpoint of solubility in a solvent, the liquid crystal polymer preferably has, as the structural unit (3), a structural unit (3) in which at least one of X or Y is an imino group, that is, preferably has as the structural unit (3), at least one of a structural unit derived from an aromatic hydroxylamine or a structural unit derived from an aromatic diamine, and it is more preferable to have only a structural unit (3) in which at least one of X or Y is an imino group.

It is preferable that the liquid crystal polymer is produced by melt-polymerizing raw material monomers corresponding to the structural units constituting the liquid crystal polymer. The melt polymerization may be carried out in the presence of a catalyst, examples of the catalyst include metal compounds such as magnesium acetate, stannous acetate, tetrabutyl titanate, lead acetate, sodium acetate, potassium acetate, and antimony trioxide, and nitrogen-containing heterocyclic compounds such as 4-(dimethylamino)pyridine and 1-methylimidazole, and nitrogen-containing heterocyclic compounds are preferably used. The melt polymerization may be further carried out by solid phase polymerization as necessary.

A flow start temperature of the liquid crystal polymer is preferably 250° C. or higher, more preferably 250° C. or higher and 350° C. or lower, and still more preferably 260° C. or higher and 330° C. or lower. In a case where the flow start temperature of the liquid crystal polymer is within the above-described range, the solubility, the heat resistance, the strength, and the rigidity are excellent, and the viscosity of the solution is appropriate.

The flow start temperature, also referred to as a flow temperature, is a temperature at which a viscosity of 4,800 Pa·s (48,000 poises) is exhibited in a case where the liquid crystal polymer is melted and extruded from a nozzle having an inner diameter of 1 mm and a length of 10 mm while the temperature is raised at a rate of 4° C./min under a load of 9.8 MPa (100 kg/cm²) using a capillary rheometer and is a guideline for the molecular weight of the liquid crystal polyester (see p. 95 of “Liquid Crystal Polymers—Synthesis/Molding/Applications—”, written by Naoyuki Koide, CMC Corporation, Jun. 5, 1987).

In addition, a weight-average molecular weight of the liquid crystal polymer is preferably 1,000,000 or less, more preferably 3,000 to 300,000, still more preferably 5,000 to 100,000, and particularly preferably 5,000 to 30,000. In a case where the weight-average molecular weight of the liquid crystal polymer is within the above-described range, a film after heat treatment is excellent in thermal conductivity, heat resistance, strength, and rigidity in the thickness direction.

—Fluorine-Based Polymer—

From the viewpoint of heat resistance and mechanical strength, the polymer having a dielectric loss tangent of 0.01 or less or the above-described polymer A is preferably a fluorine-based polymer.

In the present disclosure, the type of the fluorine-based polymer used as the polymer having a dielectric loss tangent of 0.01 or less or the above-described polymer A is not particularly limited as long as the dielectric loss tangent thereof is 0.01 or less, and a known fluorine-based polymer can be used.

Examples of the fluorine-based polymer include polytetrafluoroethylene, polychlorotrifluoroethylene, polyvinylidene fluoride, polyvinyl fluoride, a perfluoroalkoxy fluororesin, an ethylene tetrafluoride/propylene hexafluoride copolymer, an ethylene/ethylene tetrafluoride copolymer, and an ethylene/chlorotrifluoroethylene copolymer.

Among these, polytetrafluoroethylene is preferable.

In addition, examples of the fluorine-based polymer include a fluorinated α-olefin monomer, that is, an α-olefin monomer containing at least one fluorine atom; and a homopolymer and a copolymer optionally containing a structural unit derived from a non-fluorinated ethylenically unsaturated monomer reactive to the fluorinated α-olefin monomer.

Examples of the fluorinated α-olefin monomer include CF₂═CF₂, CHF═CF₂, CH₂═CF₂, CHCl═CHF, CClF═CF₂, CCl₂═CF₂, CClF═CClF, CHF═CCl₂, CH₂═CClF, CCl₂═CClF, CF₃CF═CF₂, CF₃CF═CHF, CF₃CH═CF₂, CF₃CH═CH₂, CHF₂CH═CHF, CF₃CF═CF₂, and perfluoro(alkyl having 2 to 8 carbon atoms) vinyl ether (for example, perfluoromethyl vinyl ether, perfluoropropyl vinyl ether, and perfluorooctyl vinyl ether). Among these, at least one monomer selected from the group consisting of tetrafluoroethylene (CF₂═CF₂), chlorotrifluoroethylene (CClF═CF₂), (perfluorobutyl)ethylene, vinylidene fluoride (CH₂═CF₂), and hexafluoropropylene (CF₂═CFCF₃) is preferable.

Examples of the non-fluorinated monoethylenically unsaturated monomer include ethylene, propylene, butene, and an ethylenically unsaturated aromatic monomer (for example, styrene and α-methylstyrene).

The fluorinated α-olefin monomer may be used alone or in combination of two or more thereof.

In addition, the non-fluorinated ethylenically unsaturated monomer may be used alone or in combination of two or more thereof.

Examples of the fluorine-based polymer include polychlorotrifluoroethylene (PCTFE), poly(chlorotrifluoroethylene-propylene), poly(ethylene-tetrafluoroethylene) (ETFE), poly(ethylene-chlorotrifluoroethylene) (ECTFE), poly(hexafluoropropylene), poly(tetrafluoroethylene) (PTFE), poly(tetrafluoroethylene-ethylene-propylene), poly(tetrafluoroethylene-hexafluoropropylene) (FEP), poly(tetrafluoroethylene-propylene) (FEPM), poly(tetrafluoroethylene-perfluoropropylene vinyl ether), poly(tetrafluoroethylene-perfluoroalkyl vinyl ether) (PFA) (for example, poly(tetrafluoroethylene-perfluoropropyl vinyl ether)), polyvinyl fluoride (PVF), polyvinylidene fluoride (PVDF), poly(vinylidene fluoride-chlorotrifluoroethylene), perfluoropolyether, perfluorosulfonic acid, and perfluoropolyoxetane.

The fluorine-based polymer may be used alone or in combination of two or more thereof.

The fluorine-based polymer is preferably at least one of FEP, PFA, ETFE, or PTFE. The FEP is available from Du Pont as the trade name of TEFLON (registered trademark) FEP or from DAIKIN INDUSTRIES, LTD. as the trade name of NEOFLON FEP; and the PFA is available from DAIKIN INDUSTRIES, LTD. as the trade name of NEOFLON PFA, from Du Pont as the trade name of TEFLON (registered trademark) PFA, or from Solvay Solexis as the trade name of HYFLON PFA.

The fluorine-based polymer preferably includes PTFE. The PTFE can be included as a PTFE homopolymer, a partially modified PTFE homopolymer, or a combination including one or both of these. The partially modified PTFE homopolymer preferably contains a structural unit derived from a comonomer other than tetrafluoroethylene in an amount of less than 1% by mass based on the total mass of the polymer.

The fluorine-based polymer may be a crosslinkable fluoropolymer having a crosslinkable group. The crosslinkable fluoropolymer can be crosslinked by a known crosslinking method in the related art. One of the representative crosslinkable fluoropolymers is a fluoropolymer having a (meth)acryloxy group. For example, the crosslinkable fluoropolymer can be represented by Formula:

H₂C═CR′COO—(CH₂)ₙ—R—(CH₂)ₙ—OOCR′═CH₂

in the formula, R is a fluorine-based oligomer chain having two or more structural units derived from the fluorinated α-olefin monomer or the non-fluorinated monoethylenically unsaturated monomer, R′ is H or —CH₃, and n is 1 to 4. R may be a fluorine-based oligomer chain having a structural unit derived from tetrafluoroethylene.

In order to initiate a radical crosslinking reaction through the (meth)acryloxy group in the fluorine-based polymer, by exposing the fluoropolymer having a (meth)acryloxy group to a free radical source, a crosslinked fluoropolymer network can be formed. The free radical source is not particularly limited, and suitable examples thereof include a photoradical polymerization initiator and an organic peroxide. Appropriate photoradical polymerization initiators and organic peroxides are well known in the art. The crosslinkable fluoropolymer is commercially available, and examples thereof include Viton B manufactured by Du Pont.

—Polymerized Substance of Compound which has Cyclic Aliphatic Hydrocarbon Group and Group Having Ethylenically Unsaturated Bond—

The polymer having a dielectric loss tangent of 0.01 or less or the above-described polymer A may be a polymerized substance of a compound which has a cyclic aliphatic hydrocarbon group and a group having an ethylenically unsaturated bond.

Examples of the polymerized substance of a compound which has a cyclic aliphatic hydrocarbon group and a group having an ethylenically unsaturated bond include thermoplastic resins having a structural unit formed from a monomer including a cyclic olefin such as norbornene and a polycyclic norbornene-based monomer, which is also referred to as a thermoplastic cyclic olefin-based resin.

The polymerized substance of a compound which has a cyclic aliphatic hydrocarbon group and a group having an ethylenically unsaturated bond may be a ring-opened polymer of the above-described cyclic olefin, a hydrogenated product of a ring-opened copolymer using two or more cyclic olefins, or an addition polymer of a cyclic olefin and a linear olefin or aromatic compound having an ethylenically unsaturated bond such as a vinyl group. In addition, a polar group may be introduced into the polymerized substance of a compound which has a cyclic aliphatic hydrocarbon group and a group having an ethylenically unsaturated bond.

The polymerized substance of a compound which has a cyclic aliphatic hydrocarbon group and a group having an ethylenically unsaturated bond may be used alone or in combination of two or more thereof.

A ring structure of the cyclic aliphatic hydrocarbon group may be a single ring, a fused ring in which two or more rings are fused, or a crosslinked ring.

Examples of the ring structure of the cyclic aliphatic hydrocarbon group include a cyclopentane ring, a cyclohexane ring, a cyclooctane ring, an isophorone ring, a norbornane ring, and a dicyclopentane ring.

The compound which has a cyclic aliphatic hydrocarbon group and a group having an ethylenically unsaturated bond may be a monofunctional ethylenically unsaturated compound or a polyfunctional ethylenically unsaturated compound.

The number of cyclic aliphatic hydrocarbon groups in the compound which has a cyclic aliphatic hydrocarbon group and a group having an ethylenically unsaturated bond may be 1 or more, and may be 2 or more.

It is sufficient that the polymerized substance of a compound which has a cyclic aliphatic hydrocarbon group and a group having an ethylenically unsaturated bond is a polymer obtained by polymerizing at least one compound which has a cyclic aliphatic hydrocarbon group and a group having an ethylenically unsaturated bond, and it may be a polymerized substance of two or more kinds of the compound which has a cyclic aliphatic hydrocarbon group and a group having an ethylenically unsaturated bond or a copolymer with other ethylenically unsaturated compounds having no cyclic aliphatic hydrocarbon group.

In addition, the polymerized substance of a compound which has a cyclic aliphatic hydrocarbon group and a group having an ethylenically unsaturated bond is preferably a cycloolefin polymer.

—Polyphenylene Ether—

The polymer having a dielectric loss tangent of 0.01 or less or the above-described polymer A may be a polyphenylene ether.

In a case where heat curing is performed after film formation, from the viewpoint of heat resistance and film-forming property, a weight-average molecular weight (Mw) of the polyphenylene ether is preferably 500 to 5,000 and more preferably 500 to 3,000. In addition, in a case where the heat curing is not performed, the weight-average molecular weight (Mw) of the polyphenylene ether is not particularly limited, but is preferably 3,000 to 100,000 and more preferably 5,000 to 50,000.

In the polyphenylene ether, from the viewpoint of dielectric loss tangent and heat resistance, the average number of molecular terminal phenolic hydroxyl groups per molecule (the number of terminal hydroxyl groups) is preferably 1 to 5 and more preferably 1.5 to 3.

The number of hydroxyl groups or the number of phenolic hydroxyl groups in the polyphenylene ether can be found, for example, from a standard value of a product of the polyphenylene ether. In addition, examples of the number of terminal hydroxyl groups or the number of terminal phenolic hydroxyl groups include a numerical value representing an average value of hydroxyl groups or phenolic hydroxyl groups per molecule of all polyphenylene ethers present in 1 mol of the polyphenylene ether.

The polyphenylene ether may be used alone or in combination of two or more thereof.

Examples of the polyphenylene ether include a polyphenylene ether including 2,6-dimethylphenol and at least one of bifunctional phenol or trifunctional phenol, and a compound mainly including the polyphenylene ether, such as poly(2,6-dimethyl-1,4-phenylene oxide). More specifically, for example, a compound having a structure represented by Formula (PPE) is preferable.

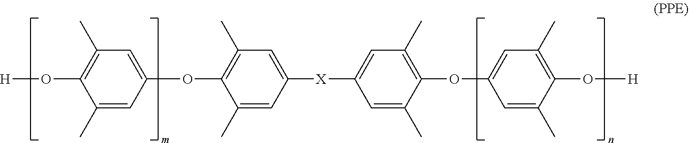

In Formula (PPE), X represents an alkylene group having 1 to 3 carbon atoms or a single bond, m represents an integer of 0 to 20, n represents an integer of 0 to 20, and the sum of m and n represents an integer of 1 to 30.

Examples of the alkylene group in X described above include a dimethylmethylene group.

—Aromatic Polyether Ketone—

The polymer having a dielectric loss tangent of 0.01 or less or the above-described polymer A may be an aromatic polyether ketone.

The aromatic polyether ketone is not particularly limited, and a known aromatic polyether ketone can be used.

The aromatic polyether ketone is preferably a polyether ether ketone.

The polyether ether ketone is one type of the aromatic polyether ketone, and is a polymer in which bonds are arranged in the order of an ether bond, an ether bond, and a carbonyl bond (ketone). It is preferable that the bonds are linked to each other by a divalent aromatic group.

The aromatic polyether ketone may be used alone or in combination of two or more thereof.

Examples of the aromatic polyether ketone include polyether ether ketone (PEEK) having a chemical structure represented by Formula (P1), polyether ketone (PEK) having a chemical structure represented by Formula (P2), polyether ketone ketone (PEKK) having a chemical structure represented by Formula (P3), polyether ether ketone ketone (PEEKK) having a chemical structure represented by Formula (P4), and polyether ketone ether ketone ketone (PEKEKK) having a chemical structure represented by Formula (P5).

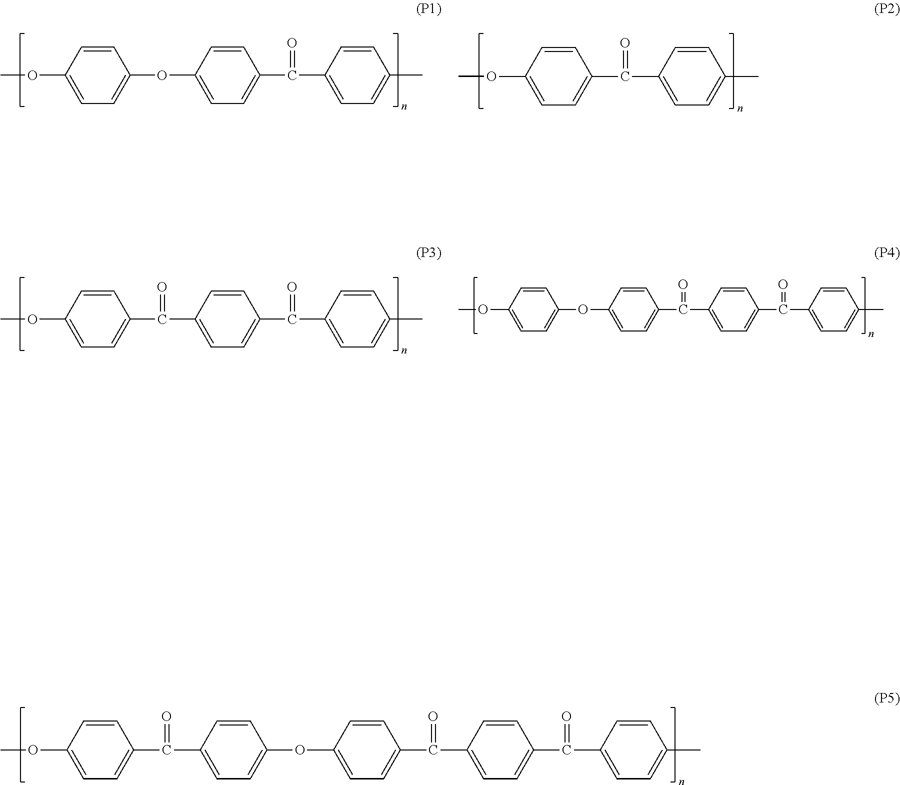

From the viewpoint of mechanical properties, each n of Formulae (P1) to (P5) is preferably 10 or more and more preferably 20 or more. On the other hand, from the viewpoint that the aromatic polyether ketone can be easily produced, n is preferably 5,000 or less and more preferably 1,000 or less. That is, n is preferably 10 to 5,000 and more preferably 20 to 1,000.

The polymer having a dielectric loss tangent of 0.01 or less is preferably a polymer soluble in a specific organic solvent (hereinafter, also referred to as “soluble polymer”).

Specifically, the soluble polymer in the present disclosure is a polymer in which 0.1 g or more thereof is dissolved at 25° C. in 100 g of at least one solvent selected from the group consisting of N-methylpyrrolidone, N-ethylpyrrolidone, dichloromethane, dichloroethane, chloroform, N,N-dimethylacetamide, γ-butyrolactone, dimethylformamide, ethylene glycol monobutyl ether, and ethylene glycol monoethyl ether.

The above-described layer B may contain only one kind of the polymer having a dielectric loss tangent of 0.01 or less or the above-described polymer A, or may contain two or more kinds thereof.

From the viewpoint of dielectric loss tangent of the polymer film and adhesiveness with the metal foil or the metal wire, a content of the polymer having a dielectric loss tangent of 0.01 or less or the above-described polymer A in the polymer film is preferably 20% by mass to 99% by mass, more preferably 30% by mass to 98% by mass, still more preferably 40% by mass to 97% by mass, and particularly preferably 50% by mass to 95% by mass with respect to the total mass of the above-described layer B.

—Filler—

From the viewpoint of adhesiveness with the metal foil or the metal wire, the layer B may contain a filler.

The filler preferably includes a needle-like filler or a filler having a protrusion.

Preferred aspects of the filler which is used in the layer B are the same as the preferred aspects of the filler which is used in the layer A described later, except as described below.

As the needle-like filler, an inorganic needle-like filler is preferable, and a needle-like filler of an inorganic oxide is more preferable.

In addition, an aspect ratio of the needle-like filler is preferably 3 or more, more preferably 5 or more, and particularly preferably 5 or more and 100 or less.

As the filler having a protrusion, an inorganic filler having a protrusion is preferable, and an inorganic oxide filler having a protrusion is more preferable.

In addition, as the filler having a protrusion, a star-shaped rock candy (Japanese confection having horned protrusions on the surface of a spherical shape)-like filler is more preferable. Suitable examples of the star-shaped rock candy-like filler include star-shaped rock candy-like silica sol described in JP2008-169102A.

From the viewpoint of adhesiveness with the metal foil or the metal wire, an average particle diameter of the needle-like filler or the filler having a protrusion is preferably 5 nm to 20 μm, more preferably 10 nm to 1 μm, still more preferably 20 nm to 500 nm, and particularly preferably 25 nm to 90 nm.

In a case where the layer A and the layer B contain a filler, from the viewpoint of thermal expansion coefficient and adhesiveness with the metal foil or the metal wire, it is preferable that a content of the filler in the layer B is smaller than a content of the filler in the layer A.

In a case where the layer B contains a filler, from the viewpoint of thermal expansion coefficient and adhesiveness with the metal foil or the metal wire, the content of the filler in the layer B is preferably 1% by mass to 70% by mass, more preferably 5% by mass to 60% by mass, and particularly preferably 10% by mass to 55% by mass with respect to the total mass of the layer B.

—Curable Compound—

The layer B preferably contains a curable compound, and more preferably contains a curable compound A which is an oligomer or a polymer.

The curable compound in the present disclosure is a compound having a curable group, and may be any of a monomer, an oligomer, or a polymer.

In addition, the above-described curable compound A is an oligomer or a polymer, and from the viewpoint of mechanical strength, a polymer is preferable.

In the present disclosure, the oligomer is a polymerized substance having a weight-average molecular weight of 1,000 or more and less than 2,000, and the polymer is a polymerized substance having a polymerization-average molecular weight of 2,000 or more.

In addition, from the viewpoint of adhesiveness with the metal foil or the metal wire and uneven distribution properties, the above-described curable compound A is preferably an oligomer or a polymer having a weight-average molecular weight of 1,000 or more, more preferably a polymer having a weight-average molecular weight of 2,000 or more, still more preferably a polymer having a weight-average molecular weight of 3,000 or more and 200,000 or less, and particularly preferably a polymer having a weight-average molecular weight of 5,000 or more and 100,000 or less.

In addition, from the viewpoint of suppressing wiring distortion, the weight-average molecular weight of the above-described curable compound A is preferably 100,000 or less, more preferably 50,000 or less, and particularly preferably 10,000 or less.

The polymer having a dielectric loss tangent of 0.01 or less may have a curable group, but it is assumed that the polymer having a dielectric loss tangent of 0.01 or less is different from the curable compound A. A dielectric loss tangent of the above-described curable compound A is preferably more than 0.01, and it is preferable that the above-described curable compound A is not a liquid crystal polymer.

In addition, in the polymer film according to the embodiment of the present disclosure, from the viewpoint of suppressing wiring distortion, it is preferable that a content of the above-described curable compound A is higher in at least one surface of the polymer film than in the inside of the polymer film.

Furthermore, from the viewpoint of suppressing wiring distortion, it is preferable that a layer C contains particles and the above-described curable compound is contained inside or on a surface of the particles.

Examples of the above-described particles include microcapsules or microgels having the above-described curable compound inside or on the surface thereof.

Among these, preferred examples thereof include microcapsules or microgels having the above-described curable compound inside.

In addition, the above-described particles are preferably organic resin particles.

It is sufficient that the number of curable groups in the curable compound is 1 or more, which may be 2 or more, and it is preferable to be 2 or more.

In addition, the curable compound may have only one kind of curable group, or two or more kinds of curable groups.

The above-described curable group is not particularly limited as long as it can be cured, and examples thereof include an ethylenically unsaturated group, an epoxy group, an oxetanyl group, an isocyanate group, an acid anhydride group, a carbodiimide group, an N-hydroxy ester group, a glyoxal group, an imide ester group, a halogenated alkyl group, a thiol group, a hydroxy group, a carboxy group, an amino group, an amide group, an aldehyde group, and a sulfonic acid group.

In a case where the above-described curable compound A is formed by a half-curing described later, the above-described curable group is preferably an ethylenically unsaturated group. In addition, in this case, it is preferable to use a polyfunctional ethylenically unsaturated compound as the curable compound.

Suitable examples of the above-described curable compound A include a thermosetting resin.

Examples of the thermosetting resin include an epoxy resin, a phenol resin, an unsaturated imide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, and a melamine resin. In addition, the thermosetting resin is not particularly limited thereto, and a known thermosetting resin can be used. These thermosetting resins can be used alone or in combination of two or more thereof.

In addition, a commercially available thermosetting resin-containing adhesive can also be used as the above-described curable compound A.

In addition, suitable examples of the above-described curable compound A include a curable compound obtained by half-curing a monomer.

As the monomer, an ethylenically unsaturated compound is preferable, and a polyfunctional ethylenically unsaturated compound is more preferable.

In addition, examples of the ethylenically unsaturated compound include a (meth)acrylate compound, a (meth)acrylamide compound, (meth)acrylic acid, a styrene compound, a vinyl acetate compound, a vinyl ether compound, and an olefin compound.

Among these, a (meth)acrylate compound is preferable.

In addition, from the viewpoint of adhesiveness with the metal foil or the metal wire, a molecular weight of the monomer is preferably 50 or more and less than 1,000, more preferably 100 or more and less than 1,000, and particularly preferably 200 or more and 800 or less.

In addition, in a case where the ethylenically unsaturated compound is contained as the above-described curable compound, the polymer film according to the embodiment of the present disclosure preferably contains a polymerization initiator. The polymerization initiator is preferably a thermal polymerization initiator or a photopolymerization initiator.

As the thermal polymerization initiator or the photopolymerization initiator, known ones can be used.

Examples of the thermal polymerization initiator include a thermal radical generator. Specific examples thereof include a peroxide initiator such as benzoyl peroxide and azobisisobutyronitrile, and an azo-based initiator.

Examples of the photopolymerization initiator include a photoradical generator. Specific examples thereof include (a) aromatic ketones, (b) an onium salt compound, (c) an organic peroxide, (d) a thio compound, (e) a hexaarylbiimidazole compound, (f) a ketooxime ester compound, (g) a borate compound, (h) an azinium compound, (i) an active ester compound, (j) a compound having a carbon halogen bond, and (k) a pyridium compound.

The polymerization initiator may be singly alone or may be used in combination of two or more kinds thereof.

A content of the polymerization initiator is preferably 0.01% by mass to 30% by mass, more preferably 0.05% by mass to 25% by mass, and still more preferably 0.1% by mass to 20% by mass with respect to the total mass of the curable compound.

The layer B may contain only one kind of the curable compound, for example, only one kind of the curable compound A, or may contain two or more kinds of the curable compounds.

In addition, the layer B may contain only one or two or more kinds of the curable compound A.

From the viewpoint of dielectric loss tangent of the polymer film and wiring distortion suppression property, a content of the curable compound in the layer B is preferably 0.1% by mass to 70% by mass, more preferably 1% by mass to 60% by mass, still more preferably 5% by mass to 60% by mass, and particularly preferably 10% by mass to 55% by mass with respect to the total mass of the layer B.

In addition, from the viewpoint of dielectric loss tangent of the polymer film and wiring distortion suppression property, a content of the curable compound A in the layer B is preferably 0.1% by mass to 70% by mass, more preferably 1% by mass to 60% by mass, still more preferably 5% by mass to 60% by mass, and particularly preferably 10% by mass to 55% by mass with respect to the total mass of the layer B.

In addition, from the viewpoint of wiring distortion suppression property, a content of the above-described curable compound A in the layer B is preferably 30% by mass to 100% by mass, more preferably 50% by mass to 100% by mass, and particularly preferably 70% by mass to 100% by mass with respect to the total mass of the above-described curable compound.

—Curing Inhibitor—

From the viewpoint of controlling a curing state and of wiring distortion suppression property, the layer B preferably contains a curing inhibitor.

Examples of the curing inhibitor include a polymerization inhibitor and a heat stabilizer, and known ones can be used for each.

Examples of the polymerization inhibitor include p-methoxyphenol, quinones (for example, hydroquinone, benzoquinone, methoxybenzoquinone, and the like), phenothiazine, catechols, alkylphenols (for example, dibutyl hydroxy toluene (BHT) and the like), alkyl bisphenols, zinc dimethyldithiocarbamate, copper dimethyldithiocarbamate, copper dibutyldithiocarbamate, copper salicylate, thiodipropionic acid esters, mercaptobenzimidazole, phosphites, 2,2,6,6-tetramethylpiperidine-1-oxyl (TEMPO), 2,2,6,6-tetramethyl-4-hydroxypiperidine-1-oxyl (TEMPOL), and tris(N-nitroso-N-phenylhydroxylamine)aluminum salt (also known as Cupferron Al).

Examples of the above-described heat stabilizer include phosphorus-based heat stabilizers such as tris(2,4-di-tert-butylphenyl)phosphite, bis[2,4-bis(1,1-dimethylethyl)-6-methylphenyl]ethyl ester phosphorous acid, tetrakis(2,4-di-tert-butylphenyl)[1,1-biphenyl]-4,4′-diylbisphosphonite, and bis(2,4-di-tert-butylphenyl)pentaerythritol diphosphite; and lactone-based heat stabilizers such as a reaction product of 8-hydroxy-5,7-di-tert-butyl-furan-2-one and o-xylene.

The curing inhibitor may be used alone or in combination of two or more thereof.

A content of the curing inhibitor is not particularly limited, but is preferably 0.0001% by mass to 2.0% by mass with respect to the total mass of the layer B.

—Other Additives—

The layer B may contain other additives in addition to the above-described additive, polymer having a dielectric loss tangent of 0.01 or less, polymer A, and filler.

Known additives can be used as the other additives. Specific examples of the other additives include a leveling agent, an antifoaming agent, an antioxidant, an ultraviolet absorbing agent, a flame retardant, and a colorant.

In addition, the layer B may contain, as the other additives, a resin other than the above-described components.

Examples of the resin other than the polymer having a dielectric loss tangent of 0.01 or less and the above-described polymer A include thermoplastic resins such as polyolefin, a cycloolefin polymer, polyamide, polyester, polyphenylene sulfide, polyether ketone, polycarbonate, polyethersulfone, polyphenylene ether and a modified product thereof, polyetherimide, a silicone resin, and a fluorine-based resin; elastomers such as a copolymer of glycidyl methacrylate and polyethylene; and thermosetting resins such as a phenol resin, an epoxy resin, a polyimide resin, and a cyanate resin.

The total content of the other additives in the layer B is preferably 25 parts by mass or less, more preferably 10 parts by mass or less, and still more preferably 5 parts by mass or less with respect to 100 parts by mass of the content of the polymer having a dielectric loss tangent of 0.01 or less or the above-described polymer A.

From the viewpoint of thermal expansion coefficient and adhesiveness with the metal foil or the metal wire, it is preferable that an average thickness of the layer B is smaller than the average thickness of the layer A.

From the viewpoint of thermal expansion coefficient and adhesiveness with the metal foil or the metal wire, a value of T^{A}/T^{B}, which is a ratio of an average thickness T^{A} of the layer A to an average thickness T^{B} of the layer B, is preferably more than 1, more preferably 1.5 to 100, still more preferably 2 to 10, and particularly preferably 2 to 5.

In addition, from the viewpoint of thermal expansion coefficient and adhesiveness with the metal foil or the metal wire, the average thickness of the layer B is preferably 3 μm to 40 μm, more preferably 5 μm to 30 μm, still more preferably 8 μm to 20 μm, and particularly preferably 10 μm to 15 μm.

<Layer A>

The layer A contains the polymer having a dielectric loss tangent of 0.01 or less or the above-described polymer A.

Preferred aspects of the polymer having a dielectric loss tangent of 0.01 or less and the above-described polymer A, used in the layer A, are the same as the preferred aspects of the polymer having a dielectric loss tangent of 0.01 or less and the above-described polymer A, used in the layer B, except as described above.

The layer A may contain only one kind of the polymer having a dielectric loss tangent of 0.01 or less or the above-described polymer A, or may contain two or more kinds thereof.

From the viewpoint of thermal expansion coefficient and adhesiveness with the metal foil or the metal wire, a content of the polymer having a dielectric loss tangent of 0.01 or less or the above-described polymer A in the layer A is preferably 20% by mass to 100% by mass, more preferably 20% by mass to 100% by mass, still more preferably 30% by mass to 100% by mass, and particularly preferably 40% by mass to 100% by mass with respect to the total mass of the layer A.

—Filler—

From the viewpoint of wiring distortion suppression property, thermal expansion coefficient, and adhesiveness between other polymer films and the metal foil or the metal wire, the layer A more preferably contains a filler.

The filler may be particulate or fibrous, and may be an inorganic filler or an organic filler.

In the polymer film according to the embodiment of the present disclosure, from the viewpoint of suppressing the distortion of the metal wire in a case where the film is adhered to the metal wire, it is preferable that a number density of the above-described filler is higher in the inside than in the surface.

As the inorganic filler, a known inorganic filler can be used.

Examples of a material of the inorganic filler include BN, Al₂O₃, AlN, TiO₂, SiO₂, barium titanate, strontium titanate, aluminum hydroxide, calcium carbonate, and a material containing two or more of these.

Among these, as the inorganic filler, from the viewpoint of thermal expansion coefficient and adhesiveness with the metal foil or the metal wire, metal oxide particles or fibers are preferable, silica particles, titania particles, or glass fibers are more preferable, and silica particles or glass fibers are particularly preferable.

From the viewpoint of thermal expansion coefficient and adhesiveness with the metal foil or the metal wire, the average particle diameter of the inorganic filler is preferably 5 nm to 20 μm, more preferably 10 nm to 10 μm, still more preferably 20 nm to 1 μm, and particularly preferably 25 nm to 500 nm. In a case where the particles or fibers are flat, the average particle diameter indicates a length in a short side direction.

As the organic filler, a known organic filler can be used.

Examples of a material of the organic filler include polyethylene, polystyrene, urea-formalin filler, polyester, cellulose, acrylic resin, fluororesin, cured epoxy resin, crosslinked benzoguanamine resin, crosslinked acrylic resin, and a material containing two or more kinds of these.

In addition, the organic filler may be fibrous, such as nanofibers, or may be hollow resin particles.

Among these, as the organic filler, from the viewpoint of thermal expansion coefficient and adhesiveness with the metal foil or the metal wire, fluororesin particles, polyester-based resin particles, or cellulose-based resin nanofibers are preferable, and polytetrafluoroethylene particles are more preferable.

From the viewpoint of thermal expansion coefficient and adhesiveness with the metal foil or the metal wire, the average particle diameter of the organic filler is preferably 5 nm to 20 μm, more preferably 10 nm to 1 μm, still more preferably 20 nm to 500 nm, and particularly preferably 25 nm to 90 nm.

The layer A may contain only one or two or more kinds of the fillers.

From the viewpoint of thermal expansion coefficient and adhesiveness with the metal foil or the metal wire, a content of the filler in the layer A is preferably 5% by mass to 80% by mass, more preferably 10% by mass to 70% by mass, still more preferably 20% by mass to 70% by mass, and particularly preferably 30% by mass to 60% by mass with respect to the total mass of the layer A.

—Other Additives—

The layer A may contain other additives in addition to the above-described polymer having a dielectric loss tangent of 0.01 or less, polymer A, and filler.

Preferred aspects of other additives which are used in the layer A are the same as the preferred aspects of other additives which are used in the layer B.

An average thickness of the layer A is not particularly limited, but from the viewpoint of thermal expansion coefficient and adhesiveness with the metal foil or the metal wire, the average thickness thereof is preferably 5 μm to 400 μm, more preferably 10 μm to 100 μm, and particularly preferably 15 μm to 50 μm.

A method for measuring the average thickness of each layer in the polymer film according to the embodiment of the present disclosure is as follows.

The thickness of each layer is evaluated by cutting the polymer film with a microtome and observing the cross section with an optical microscope. Three or more sites of the cross-sectional sample are cut out, the thickness is measured at three or more points in each cross section, and the average value thereof is defined as the average thickness.

The polymer film is cut along a plane perpendicular to a plane direction of the polymer film, thicknesses are measured at five or more points on a cross section thereof, and an average value thereof is defined as the average thickness.

<Layer C>

It is preferable that the polymer film according to the embodiment of the present disclosure further includes a layer C, and it is more preferable that the above-described layer B, the above-described layer A, and the layer C are provided in this order.

In addition, the layer C is preferably a surface layer (outermost layer).

From the viewpoint of thermal expansion coefficient and adhesiveness with the metal foil or the metal wire, the layer C preferably contains the polymer having a dielectric loss tangent of 0.01 or less or the above-described polymer A.

Preferred aspects of the polymer having a dielectric loss tangent of 0.01 or less and the above-described polymer A, used in the layer C, are the same as the preferred aspects of the polymer having a dielectric loss tangent of 0.01 or less and the above-described polymer A, used in the layer B, except as will be described below.

The polymer having a dielectric loss tangent of 0.01 or less the above-described polymer A, contained in the layer C, may be the same as or different from the polymer having a dielectric loss tangent of 0.01 or less or the above-described polymer A, contained in the layer A or the layer B, but it is preferable to be the same as the polymer having a dielectric loss tangent of 0.01 or less or the above-described polymer A, contained in the layer A or the layer B.

From the viewpoint of thermal expansion coefficient and adhesiveness with the metal foil or the metal wire, it is preferable that a content of the polymer having a dielectric loss tangent of 0.01 or less or the above-described polymer A in the layer C is smaller than the content of the polymer having a dielectric loss tangent of 0.01 or less or the above-described polymer A in the layer A.

In addition, from the viewpoint of thermal expansion coefficient and adhesiveness with the metal foil or the metal wire, the content of the polymer having a dielectric loss tangent of 0.01 or less or the above-described polymer A in the layer C is preferably 10% by mass to 99.99% by mass, more preferably 20% by mass to 99.9% by mass, still more preferably 30% by mass to 95% by mass, and particularly preferably 30% by mass to 90% by mass with respect to the total mass of the layer C.

The layer C may contain a filler.

Preferred aspects of the filler which is used in the layer C are the same as the preferred aspects of the filler which is used in the layer B.

In addition, the layer C preferably contains a curable compound, and more preferably contains a curable compound and a curing inhibitor.

Preferred aspects of the curable compound and the curing inhibitor, used in the layer C, are the same as the preferred aspects of the curable compound and the curing inhibitor, used in the layer B.

The layer C may contain other additives, in addition to the above-described polymer having a dielectric loss tangent of 0.01 or less, polymer A, filler, curable composition, and curing inhibitor.

Preferred aspects of the other additives which are used in the layer C are the same as the preferred aspects of the other additives which are used in the layer A.

From the viewpoint of thermal expansion coefficient and adhesiveness with the metal foil or the metal wire, it is preferable that an average thickness of the layer C is smaller than the average thickness of the layer A.

From the viewpoint of thermal expansion coefficient and adhesiveness with the metal foil or the metal wire, a value of T^{A}/T^{C}, which is a ratio of an average thickness T^{A} of the layer A to an average thickness T^{C} of the layer C, is preferably more than 1, more preferably 1.5 to 100, still more preferably 2 to 50, and particularly preferably 2 to 30.

In addition, from the viewpoint of thermal expansion coefficient and adhesiveness with the metal foil or the metal wire, a value of T^{C}/T^{B}, which is a ratio of the average thickness T^{C} of the layer C to the average thickness T^{B} of the layer B, is preferably 0.01 to 5, more preferably 0.05 to 1, and particularly preferably 0.1 to 0.5.

Furthermore, from the viewpoint of thermal expansion coefficient and adhesiveness with the metal foil or the metal wire, the average thickness of the layer C is preferably 0.1 μm to 40 μm, more preferably 0.5 μm to 20 μm, still more preferably 1 μm to 10 μm, and particularly preferably 1 μm to 3 μm.

From the viewpoint of strength, thermal expansion coefficient, and adhesiveness with the metal foil or the metal wire, an average thickness of the polymer film according to the embodiment of the present disclosure is preferably 6 μm to 200 μm, more preferably 12 μm to 100 μm, and particularly preferably 20 μm to 60 μm.

The average thickness of the polymer film is measured at optional five sites using an adhesive film thickness meter, for example, an electronic micrometer (product name, “KG3001A”, manufactured by Anritsu Corporation), and the average value of the measured values is defined as the average thickness of the polymer film.

From the viewpoint of thermal expansion coefficient, a linear expansion coefficient of the polymer film according to the embodiment of the present disclosure is preferably −20 ppm/K to 50 ppm/K, more preferably −10 ppm/K to 40 ppm/K, still more preferably 0 ppm/K to 35 ppm/K, and particularly preferably 10 ppm/K to 30 ppm/K.

The linear expansion coefficient in the present disclosure is measured by the following method.

A tensile load of 1 g is applied to both ends of a polymer film or each layer having a width of 5 mm and a length of 20 mm, and a linear expansion coefficient is calculated from the inclination of TMA curve between 30° C. and 150° C. using a thermomechanical analyzer (TMA) in a case where the temperature is raised from 25° C. to 200° C. at a rate of 5° C./min, lowered to 30° C. at a rate of 20° C./min, and raised again at a rate of 5° C./min.

In a case where each layer is measured, a measurement sample may be produced by scraping off the layer to be measured with a razor or the like.

In addition, in a case where it is difficult to measure the linear expansion coefficient by the above-described method, the measurement is carried out by the following method.

The film is cut with a microtome to produce a section sample, and the section sample is set in an optical microscope equipped with a heating stage system (HS82, manufactured by METTLER TOLEDO). Subsequently, the section sample was heated from 25° C. to 200° C. at a rate of 5° C./min, cooled to 30° C. at a rate of 20° C./min, and then heated again at a rate of 5° C./min, and a thickness of the polymer film or each layer at 30° C. (ts30) and a thickness of the polymer film or each layer at 150° C. (ts150) are evaluated. Thereafter, a value obtained by dividing the dimensional change by the temperature change ((ts150−ts30)/(150−30)) is calculated to obtain the linear expansion coefficient of the polymer film or each layer.

From the viewpoint of reducing transmission loss of the produced substrate, the dielectric loss tangent of the polymer film according to the embodiment of the present disclosure is preferably 0.005 or less, more preferably 0.004 or less, still more preferably 0.0035 or less, and particularly preferably more than 0 and 0.003 or less.

<Method for Manufacturing Polymer Film>

[Film Formation]

A method for manufacturing the polymer film according to the embodiment of the present disclosure is not particularly limited, and a known method can be referred to.

Suitable examples of the method for manufacturing the polymer film according to the embodiment of the present disclosure include a co-casting method, a multilayer coating method, and a co-extrusion method. Among these, the co-casting method is particularly preferable for formation of a relatively thin film, and the co-extrusion method is particularly preferable for formation of a thick film.

In a case where the film is manufactured by the co-casting method or the multilayer coating method, it is preferable that the co-casting method or the multilayer coating method is performed by using a composition for forming the layer A, a composition for forming the layer B, a composition for forming the layer C, or the like obtained by dissolving or dispersing components of each layer such as the liquid crystal polymer in a solvent.

Examples of the solvent include halogenated hydrocarbons such as dichloromethane, chloroform, 1,1-dichloroethane, 1,2-dichloroethane, 1,1,2,2-tetrachloroethane, 1-chlorobutane, chlorobenzene, and o-dichlorobenzene; halogenated phenols such as p-chlorophenol, pentachlorophenol, and pentafluorophenol; ethers such as diethyl ether, tetrahydrofuran, and 1,4-dioxane; ketones such as acetone and cyclohexanone; esters such as ethyl acetate and γ-butyrolactone; carbonates such as ethylene carbonate and propylene carbonate; amines such as triethylamine; nitrogen-containing heterocyclic aromatic compounds such as pyridine; nitriles such as acetonitrile and succinonitrile; amides such as N,N-dimethylformamide, N,N-dimethylacetamide, and N-methylpyrrolidone; urea compounds such as tetramethylurea; nitro compounds such as nitromethane and nitrobenzene; sulfur compounds such as dimethyl sulfoxide and sulfolane; and phosphorus compounds such as hexamethylphosphoramide and tri-n-butyl phosphate. Among these, two or more kinds thereof may be used in combination.

From the viewpoint of low corrosiveness and satisfactory handleability, a solvent containing, as a main component, an aprotic compound, particularly an aprotic compound having no halogen atom is preferable as the solvent, and the proportion of the aprotic compound in the entire solvent is preferably 50% by mass to 100% by mass, more preferably 70% by mass to 100% by mass, and particularly preferably 90% by mass to 100% by mass. In addition, from the viewpoint of easily dissolving the liquid crystal polymer, as the above-described aprotic compound, it is preferable to use an amide such as N,N-dimethylformamide, N,N-dimethylacetamide, tetramethylurea, and N-methylpyrrolidone, or an ester such as γ-butyrolactone; and it is more preferable to use N,N-dimethylformamide, N,N-dimethylacetamide, or N-methylpyrrolidone.

In addition, as the solvent, from the viewpoint of easily dissolving the liquid crystal polymer, a solvent containing a compound having a dipole moment of 3 to 5 as a main component is preferable, and a proportion of the compound having a dipole moment of 3 to 5 in the entire solvent is preferably 50% by mass to 100% by mass, more preferably 70% by mass to 100% by mass, and particularly preferably 90% by mass to 100% by mass.

It is preferable to use the compound having a dipole moment of 3 to 5 as the above-described aprotic compound.

In addition, as the solvent, from the viewpoint of ease removal, a solvent containing, as a main component, a compound having a boiling point of 220° C. or lower at 1 atm is preferable, and a proportion of the compound having a boiling point of 220° C. or lower at 1 atm in the entire solvent is preferably 50% by mass to 100% by mass, more preferably 70% by mass to 100% by mass, and particularly preferably 90% by mass to 100% by mass.

It is preferable to use the compound having a boiling point of 220° C. or lower at 1 atm as the above-described aprotic compound.

In addition, in a case where the polymer film according to the embodiment of the present disclosure is manufactured by a manufacturing method such as the co-casting method, the multilayer coating method, and the co-extrusion method, a support may be used. In addition, in a case where the metal layer (metal foil) or the like used in the laminate described later is used as the support, the support may be used as it is without being peeled off.

Examples of the support include a metal drum, a metal band, a glass plate, a resin film, and a metal foil. Among these, a metal drum, a metal band, or a resin film is preferable.

Examples of the resin film include a polyimide (PI) film, and examples of commercially available products thereof include U-PILEX S and U-PILEX R (manufactured by Ube Corporation), KAPTON (manufactured by Du Pont-Toray Co., Ltd.), and IF30, IF70, and LV300 (manufactured by SKC Kolon PI, Inc.).

In addition, the support may have a surface treatment layer formed on the surface so that the support can be easily peeled off. Hard chrome plating, a fluororesin, or the like can be used as the surface treatment layer.

An average thickness of the resin film support is not particularly limited, but is preferably 25 μm or more and 75 μm or less and more preferably 50 μm or more and 75 μm or less.

In addition, a method for removing at least a part of the solvent from a cast or applied film-like composition (a casting film or a coating film) is not particularly limited, and a known drying method can be used.

[Stretching]

In the liquid crystal polymer film according to the embodiment of the present disclosure, stretching can be combined as appropriate from the viewpoint of controlling molecular alignment and adjusting linear expansion coefficient and mechanical properties. The stretching method is not particularly limited, and a known method can be referred to, and the stretching method may be carried out in a solvent-containing state or in a dry film state. The stretching in the solvent-containing state may be carried out by gripping and stretching the film, by utilizing a self-contractile force of a web due to drying without stretching the film, or by combining these methods. The stretching is particularly effective for the purpose of improving the breaking elongation and the breaking strength, in a case where brittleness of the film is reduced by addition of an inorganic filler or the like.

[Heat Treatment]

The method for manufacturing the polymer film according to the embodiment of the present disclosure preferably includes a step of heat-treating (annealing) the polymer film.

From the viewpoint of mechanical strength of the web during the manufacturing process and breaking strength of the polymer film to be manufactured, a heat treatment temperature in the above-described heat treatment step is preferably a temperature equal to or less than the melting point Tm of the polymer having a dielectric loss tangent of 0.01 or less or the above-described polymer A.

Furthermore, specifically, from the viewpoint of breaking strength, the heat treatment temperature in the above-described step of heat-treating is more preferably 260° C. to 370° C., and more preferably 310° C. to 350° C. The annealing time is preferably 30 minutes to 5 hours, and more preferably 30 minutes to 3 hours.

In addition, the method for manufacturing the polymer film according to the embodiment of the present disclosure may include other known steps as necessary.

<Applications>

The polymer film according to the embodiment of the present disclosure can be used for various applications. Among the various applications, the polymer film can be used suitably as a film for an electronic component such as a printed wiring board and more suitably for a flexible printed circuit board.

In addition, the polymer film according to the embodiment of the present disclosure can be suitably used as a polymer film for metal adhesion.

(Laminate)

The laminate according to the embodiment of the present disclosure may be one in which the polymer film according to the embodiment of the present disclosure is laminated, but it is preferable to include the polymer film according to the embodiment of the present disclosure and a metal layer or metal wire disposed on at least one surface of the polymer film, and it is more preferable to include the polymer film according to the embodiment of the present disclosure and a copper layer or copper wire disposed on at least one surface of the polymer film.

In addition, the laminate according to the embodiment of the present disclosure preferably includes a metal layer or metal wire, the polymer film according to the embodiment of the present disclosure, and a metal layer or metal wire in this order, and more preferably includes a copper layer or copper wire, the polymer film according to the embodiment of the present disclosure, and a copper layer or copper wire.

Furthermore, the laminate according to the embodiment of the present disclosure preferably includes the polymer film according to the embodiment of the present disclosure, a copper layer or copper wire, the polymer film according to the embodiment of the present disclosure, a metal layer or metal wire, and the polymer film according to the embodiment of the present disclosure in this order. Two polymer films according to the embodiment of the present disclosure used for the above-described laminate may be the same or different from each other.

The above-described metal layer and metal wire are not particularly limited and may be any known metal layer or metal wire, but for example, a silver layer, a silver wire, a copper layer, or a copper wire is preferable, and a copper layer or a copper wire is more preferable.

In addition, the above-described metal layer and metal wire are preferably metal wire.

Furthermore, the metal in the above-described metal layer and metal wire is preferably silver or copper, and more preferably copper.

Since the polymer film according to the embodiment of the present disclosure can be further cured, for example, after attaching the metal layer or metal wire, from the viewpoint of durability, it is preferable that the laminate according to the embodiment of the present disclosure includes a cured substance obtained by curing the above-described curable compound A.

In addition, it is preferable that the laminate according to the embodiment of the present disclosure includes the polymer film according to the embodiment of the present disclosure in which the layer B, the layer A, and the layer C are provided in this order, a metal layer disposed on a surface of the above-described layer B side of the polymer film, and a metal layer disposed on a surface of the above-described layer C side of the polymer film; and it is more preferable that both of the metal layers are copper layers.

The metal layer disposed on the surface of the above-described layer B side is preferably a metal layer disposed on the surface of the above-described layer B.

It is preferable that the metal layer disposed on the surface of the above-described layer C side is a metal layer disposed on the surface of the above-described layer C, and it is more preferable that the metal layer disposed on the surface of the above-described layer B side is a metal layer disposed on the surface of the above-described layer B, and the metal layer disposed on the surface of the above-described layer C side is a metal layer disposed on the surface of the above-described layer C.

In addition, the metal layer disposed on the surface of the above-described layer B side and the metal layer disposed on the surface of the above-described layer C side may be a metal layer having the same material, thickness, and shape, or may be metal layers having different materials, thicknesses, and shapes. From the viewpoint of adjusting the characteristic impedance, the metal layer disposed on the surface of the above-described layer B side and the metal layer disposed on the surface of the above-described layer C side may be metal layers having different materials or thicknesses, or a metal layer may be laminated on only one side of the layer B or the layer C.

A method of attaching the polymer film according to the embodiment of the present disclosure to the metal layer or the metal wire is not particularly limited, and a known laminating method can be used.

A peel strength between the above-described polymer film and the above-described copper layer is preferably 0.5 kN/m or more, more preferably 0.7 kN/m or more, still more preferably 0.7 kN/m to 2.0 kN/m, and particularly preferably 0.9 kN/m to 1.5 kN/m.

In the present disclosure, the peel strength between the polymer film and the metal layer (for example, the copper layer) is measured by the following method.

A peeling test piece with a width of 1.0 cm is produced from the laminate of the polymer film and the metal layer, the polymer film is fixed to a flat plate with double-sided adhesive tape, and the strength (kN/m) in a case of peeling the polymer film off from the metal layer at a rate of 50 mm/min is measured by the 180° method in conformity with JIS C 5016 (1994).

The metal layer is preferably a silver layer or a copper layer, and more preferably a copper layer. As the copper layer, a rolled copper foil formed by a rolling method or an electrolytic copper foil formed by an electrolytic method is preferable, and a rolled copper foil is more preferable from the viewpoint of bending resistance.

An average thickness of the metal layer, preferably the copper layer, is not particularly limited, but is preferably 2 μm to 20 μm, more preferably 3 μm to 18 μm, and still more preferably 5 μm to 12 μm. The copper foil may be copper foil with a carrier formed on a support (carrier) so as to be peelable. As the carrier, a known carrier can be used. An average thickness of the carrier is not particularly limited, but is preferably 10 μm to 100 μm and more preferably 18 μm to 50 μm.

In addition, from the viewpoint of further exhibiting the effects of the present disclosure, it is preferable that the above-described metal layer contains a group capable of interacting with the above-described polymer film on the surface of the metal layer on the side in contact with the polymer film. In addition, it is preferable that the above-described interactable group is a group corresponding to the functional group of the compound having a functional group, which is contained in the above-described polymer film, such as an amino group and an epoxy group, and a hydroxy group and an epoxy group.

Examples of the interactable group include a group mentioned as the functional group in the above-described compound having a functional group.

Among these, from the viewpoint of adhesiveness and ease of performing a treatment, a covalent-bondable group is preferable, an amino group or a hydroxy group is more preferable, and an amino group is particularly preferable.

It is also preferable that the metal layer in the laminate according to the embodiment of the present disclosure is processed into, for example, a desired circuit pattern by etching to form a flexible printed circuit board. The etching method is not particularly limited, and a known etching method can be used.

The method for manufacturing a laminate according to the embodiment of the present disclosure preferably includes a lamination step of laminating the above-described polymer film with the metal layer or the metal wire; more preferably includes a lamination step of laminating the above-described polymer film with the copper layer or the copper wire at a temperature of (a melting point of the above-described additive−30° C.) or higher and (the melting point+30° C.) or lower or a lamination step of laminating the above-described polymer film with the copper layer or the copper wire at a pressure of (a pressure at which the elastic modulus of the above-described layer B changes−5 MPa) or more and (the pressure at which the elastic modulus of the above-described layer B changes+10 MPa) or less; and particularly preferably includes a step of laminating the above-described polymer film with the copper layer or the copper wire at a temperature of (a melting point of the above-described additive−30° C.) or higher and (the melting point+30° C.) or lower and a step of laminating the above-described polymer film with the copper layer or the copper wire at a pressure of (a pressure at which the elastic modulus of the above-described layer B changes−5 MPa) or more and (the pressure at which the elastic modulus of the above-described layer B changes+10 MPa) or less.

In addition, in the above-described lamination step, it is preferable to laminate with the metal wire.

A laminating method in the above-described lamination step is not particularly limited, and a known laminating method can be used.

A laminating pressure in the above-described lamination step is not particularly limited, but is preferably 0.1 MPa or more and more preferably 0.2 MPa to 10 MPa.

In addition, from the viewpoint of wiring distortion suppression property, the laminating pressure in the above-described lamination step is preferably (the pressure at which the elastic modulus of the above-described layer B changes−5 MPa) or more and (the pressure at which the elastic modulus of the above-described layer B changes+10 MPa) or less, and more preferably (the pressure at which the elastic modulus of the above-described layer B changes−5 MPa) or more and (the pressure at which the elastic modulus of the above-described layer B changes+5 MPa) or less.

A laminating temperature in the above-described lamination step can be appropriately selected depending on the film or the like to be used, but is preferably 150° C. or higher, more preferably 280° C. or higher, and particularly preferably 280° C. or higher and 420° C. or lower.

In addition, from the viewpoint of wiring distortion suppression property, the laminating temperature in the above-described lamination step is preferably a temperature of (melting point of the above-described additive−30° C.) or higher and (the melting point+50° C.) or lower, more preferably a temperature of (melting point of the above-described additive −30° C.) or higher and (the melting point+30° C.) or lower, and particularly preferably a temperature of (melting point of the above-described additive−20° C.) or higher and (the melting point+20° C.) or lower.

### EXAMPLES

Hereinafter, the present disclosure will be described in more detail with reference to examples. The materials, the used amounts, the proportions, the treatment contents, the treatment procedures, and the like described in the following examples can be appropriately changed without departing from the gist of the present disclosure. Therefore, the scope of the present disclosure is not limited to the following specific examples.

«Measurement Method»

[Dielectric Loss Tangent]

The dielectric loss tangent was measured by a resonance perturbation method at a frequency of 10 GHz. A 10 GHz cavity resonator (CP531 of Kanto Electronics Application & Development Inc.) was connected to a network analyzer (“E8363B” manufactured by Agilent Technology), a sample (width: 2.0 mm×length: 80 mm) of the film was inserted into the cavity resonator, and the dielectric loss tangent of the film was measured based on a change in resonance frequency for 96 hours before and after the insertion in an environment of a temperature of 25° C. and a humidity of 60% RH.

[Elastic Modulus]

A sample for evaluating a cross section was produced by embedding the film in an ultraviolet curable (UV) resin and cutting the film with a microtome. Subsequently, storage elastic modulus of each layer was calculated by observing the sample in a VE-AFM mode using a scanning probe microscope (SPA400, manufactured by Hitachi High-Tech Science Corporation).

«Production Example»

<Liquid Crystal Polymer>

LC-A: Liquid crystal polymer produced by production method described below

—Production of LC-A—

940.9 g (5.0 mol) of 6-hydroxy-2-naphthoic acid, 377.9 g (2.5 mol) of 4-hydroxyacetaminophen, 415.3 g (2.5 mol) of isophthalic acid, and 867.8 g (8.4 mol) of acetic acid anhydride were added to a reactor provided with a stirrer, a torque meter, a nitrogen gas introduction pipe, a thermometer, and a reflux condenser, the gas inside the reactor was replaced with nitrogen gas, and the mixture was heated from room temperature (23° C.) to 140° C. over 60 minutes while being stirred in a nitrogen gas stream and was refluxed at 140° C. for 3 hours.

Thereafter, the mixture was heated from 150° C. to 300° C. over 5 hours while distilling off by-product acetic acid and unreacted acetic acid anhydride and maintained at 300° C. for 30 minutes, and the resultant was taken out from the reactor and cooled to room temperature. The obtained solid matter was crushed with a crusher, thereby obtaining powdery liquid crystal polyester (A1). The flow start temperature of the liquid crystal polyester (A1) was 193.3° C.

The liquid crystal polyester (A1) obtained above was heated from room temperature to 160° C. over 2 hours and 20 minutes in a nitrogen atmosphere, further heated from 160° C. to 180° C. over 3 hours and 20 minutes, maintained at 180° C. for 5 hours to carry out solid phase polymerization, cooled, and crushed with a crusher, thereby obtaining powdery liquid crystal polyester (A2). The flow start temperature of the liquid crystal polyester (A2) was 220° C.

The liquid crystal polyester (A2) obtained above was heated from room temperature (23° C.) to 180° C. over 1 hour and 25 minutes in a nitrogen atmosphere, further heated from 180° C. to 255° C. over 6 hours and 40 minutes, maintained at 255° C. for 5 hours to carry out solid phase polymerization, and cooled, thereby obtaining powdery liquid crystal polyester (A) (LC-A). A flow start temperature of the liquid crystal polyester (A) was 302° C. In addition, in a case where a melting point of the liquid crystal polyester (A) was measured using a differential scanning calorimetry device, the measured value was 311° C.

LC-B: Liquid crystal polymer produced by production method described below

—Production of LC-B—

940.9 g (5.0 mol) of 6-hydroxy-2-naphthoic acid, 377.9 g (2.5 mol) of 4-hydroxyacetaminophen, 415.3 g (2.5 mol) of isophthalic acid, and 867.8 g (8.4 mol) of acetic acid anhydride were added to a reactor provided with a stirrer, a torque meter, a nitrogen gas introduction pipe, a thermometer, and a reflux condenser, the gas inside the reactor was replaced with nitrogen gas, and the mixture was heated from room temperature (23° C.) to 143° C. over 60 minutes while being stirred in a nitrogen gas stream and was refluxed at 143° C. for 1 hour.

Thereafter, the mixture was heated from 150° C. to 300° C. over 5 hours while distilling off by-product acetic acid and unreacted acetic acid anhydride and maintained at 300° C. for 30 minutes, and the resultant was taken out from the reactor and cooled to room temperature. The obtained solid matter was crushed with a crusher, thereby obtaining powdery liquid crystal polyester (B1).

The liquid crystal polyester (B1) obtained above was heated from room temperature to 160° C. over 2 hours and 20 minutes in a nitrogen atmosphere, further heated from 160° C. to 180° C. over 3 hours and 20 minutes, maintained at 180° C. for 5 hours to carry out solid phase polymerization, cooled, and crushed with a crusher, thereby obtaining powdery liquid crystal polyester (B2).

The liquid crystal polyester (B2) obtained above was heated from room temperature (23° C.) to 180° C. over 1 hour and 20 minutes in a nitrogen atmosphere, further heated from 180° C. to 240° C. over 5 hours, maintained at 240° C. for 5 hours to carry out solid phase polymerization, and cooled, thereby obtaining powdery liquid crystal polyester (B) (LC-B).

LC-D: Liquid crystal polymer produced by production method described below

—Production of LC-D—

941 g (5.0 mol) of 6-hydroxy-2-naphthoic acid, 273 g (2.5 mol) of 4-aminophenol, 415 g (2.5 mol) of isophthalic acid, and 1123 g (11 mol) of acetic acid anhydride were added to a reactor provided with a stirrer, a torque meter, a nitrogen gas introduction pipe, a thermometer, and a reflux condenser, the gas inside the reactor was replaced with nitrogen gas, and the mixture was heated from room temperature (23° C.) to 150° C. over 15 minutes while being stirred in a nitrogen gas stream and was refluxed at 150° C. for 3 hours.

Thereafter, the mixture was heated from 150° C. to 320° C. over 3 hours while distilling off by-product acetic acid and unreacted acetic acid anhydride and maintained until an increase in viscosity was observed, and the resultant was taken out from the reactor and cooled to room temperature. The obtained solid matter was crushed with a crusher, thereby obtaining powdery liquid crystal polyester (D1).

The liquid crystal polyester (D1) obtained above was maintained at 250° C. for 3 hours in a nitrogen atmosphere to carry out solid phase polymerization, cooled, and crushed with a crusher, thereby obtaining powdery liquid crystal polyester (LC-D).

<Additive>

A-1: Commercially available saturated copolymerized polyester resin (Elitel UE-9900, softening point (inflection point of change in elastic modulus due to change in temperature): 137° C., manufactured by UNITIKA LTD.) was crushed and used so that the amount of solid content was the amount shown in Table 1.

A-2: Commercially available ultrahigh-molecular-weight polyethylene fine particles having an average particle diameter of 10 μm (Mipelon PM200, melting point: 136° C., manufactured by MITSUI FINE CHEMICAL Inc.) were used so that the amount of solid content was the amount shown in Table 1.

A-3: Commercially available low-density polyethylene fine particles having an average particle diameter of 11 μm (FLO-BEADS CL-2080, manufactured by SUMITOMO SEIKA CHEMICALS CO., LTD.) were used so that the amount of solid content was the amount shown in Table 1.

A-4: Elastomer particles produced by production method described below

3 parts by mass of an epoxy resin (M-3 described later), 50 parts by mass of silica (F-5 described later), and toluene were added to 100 parts by mass of a commercially available hydrogenated styrene-based thermoplastic elastomer (TUFTEC M1913, manufactured by Asahi Kasei Corporation, carboxyl group equivalent: 5,400 g/eq, styrene/ethylene-butylene ratio: 30/70), and the mixture was stirred to obtain an elastomer composition.

The obtained elastomer composition was dried to remove toluene, and freeze crushing was performed to obtain elastomer particles (A-4).

A-5: Commercially available acrylic rubber fine particle-containing epoxy resin (ACRYSET BPF307, manufactured by NIPPON SHOKUBAI CO., LTD.) was used so that the amount of solid content was the amount shown in Table 1.

F-1: Commercially available hydrophobic silica having an average primary particle diameter of 16 nm (R972 (surface-treated with dimethyldichlorosilane), manufactured by Nippon Aerosil Co., Ltd.) was used so that the amount of solid content was the amount shown in Table 1.

F-2: Liquid crystal polymer produced by a production method described below

—Production of LC-C—

1034.99 g (5.5 mol) of 2-hydroxy-6-naphthoic acid, 378.33 g (1.75 mol) of 2,6-naphthalenedicarboxylic acid, 83.07 g (0.5 mol) of terephthalic acid, 272.52 g (2.475 mol; 0.225 mol excess with respect to the total molar amount of 2,6-naphthalenedicarboxylic acid and terephthalic acid) of hydroquinone, 1226.87 g (12 mol) of acetic acid anhydride, and 0.17 g of 1-methylimidazole as a catalyst were added to a reactor provided with a stirrer, a torque meter, a nitrogen gas introduction pipe, a thermometer, and a reflux condenser. After the gas in the reactor was replaced with nitrogen gas, the mixture was heated from room temperature to 145° C. over 15 minutes while being stirred in a nitrogen gas stream and was refluxed at 145° C. for 1 hour.

Next, the mixture was heated from 145° C. to 310° C. over 3 hours 30 minutes while distilling off by-product acetic acid and unreacted acetic acid anhydride and maintained at 310° C. for 3 hours, and solid liquid crystal polyester (LC-C) was taken out and cooled to room temperature. A flow start temperature of the polyester (LC-C) was 265° C.

[Production of Liquid Crystal Polyester Particles (F-2)]

Using a jet mill (“KJ-200” manufactured by KURIMOTO Ltd.), the liquid crystal polyester (LC-C) was crushed to obtain liquid crystal polyester particles (F-2). An average particle diameter of the liquid crystal polyester particles was 9 μm.

F-3: Commercially available silica fine particles having an average particle diameter of 0.5 μm (SO-C2, manufactured by Admatechs) were used so that the amount of solid content was the amount shown in Table 1.

F-4: Boron nitride particles (melting point>500° C., HP40MF100 (manufactured by Mizushima Ferroalloy Co., Ltd.), dielectric loss tangent: 0.0007)

F-5: Commercially available silica fine particles having an average particle diameter of 0.5 μm (SC2050-MB, manufactured by Admatechs)

M-1: Commercially available low dielectric adhesive (varnish of SLK (manufactured by Shin-Etsu Chemical Co., Ltd.) containing mainly a polymer-type curable compound was used)

M-2: Commercially available aminophenol-type epoxy resin (jER630LSD, manufactured by Mitsubishi Chemical Corporation.) was used so that the amount of solid content was the amount shown in Table 1.

M-3: Commercially available epoxy resin (jER YX8800, manufactured by Mitsubishi Chemical Corporation.)

### Examples 1 to 12 and Comparative Example 1

A film was formed and a single-sided copper-clad laminated plate was produced according to the following casting.

[Co-Casting A (Solution Film Formation)]

—Preparation of Polymer Solution—

The above-described liquid crystal polymer and the additive were added to N-methylpyrrolidone, and the mixture was stirred at 140° C. for 4 hours in a nitrogen atmosphere, thereby obtaining a liquid crystal polymer solution. The liquid crystal polymer and the additive were added thereto in the volume ratios shown in Table 1.

Subsequently, first, the solution was allowed to pass through a sintered fiber metal filter having a nominal pore diameter of 10 μm and allowed to pass through a sintered fiber metal filter having the same nominal pore diameter of 10 μm, thereby obtaining each polymer solution.

In a case where the additive was not dissolved in N-methylpyrrolidone, or in a case where the additive denatured at 140° C., a polymer solution was prepared without adding the additive, the mixture was allowed to pass through the above-described sintered fiber metal filter, and then the additive was added thereto and stirred.

—Production of Single-Sided Copper-Clad Laminated Plate—

The obtained polymer solutions for the layer A, for the layer B, and for the layer C were fed to a casting die equipped with a feedblock adapted for co-casting, and cast onto a treated surface of a copper foil (manufactured by FUKUDA METAL FOIL & POWER CO., LTD., CF-T9DA-SV-12, average thickness: 12 μm) so that the layer C was in contact with the copper foil. The polymer solutions were dried at 40° C. for 4 hours and then at 120° C. for 3 hours to remove the solvent from the casting film, a laminate (single-sided copper-clad laminated plate) having a copper layer and a film was obtained.

—Production of Double-Sided Copper-Clad Laminated Plate (Production Example 1 and Production Example 2)—

˜Copper-Clad Laminated Plate Precursor Step˜

A copper foil (manufactured by FUKUDA METAL FOIL & POWER CO., LTD., CF-T9DA-SV-12, average thickness: 12 μm) was placed on the obtained single-sided copper-clad laminated plate such that a treated surface of the copper foil was in contact with the film, and using a laminator (“Vacuum laminator V-130” manufactured by Nikko-Materials Co., Ltd.), lamination was performed for 1 minute under conditions of 140° C. and a laminating pressure of 0.4 MPa, thereby obtaining a double-sided copper foil laminated plate precursor.

˜Main Thermocompression Step˜

Using a thermocompression machine (“MP-SNL” manufactured by Toyo Seiki Seisaku-sho, Ltd.), the obtained copper-clad laminated plate precursor was subjected to thermocompression under conditions of 300° C. and 4.5 MPa for 60 minutes to produce a double-sided copper-clad laminated plate.

[Co-Casting B (Solution Film Formation)]

—Preparation of Polymer Solution—

The above-described liquid crystal polymer and the additive were added to N-methylpyrrolidone, and the mixture was stirred at 140° C. for 4 hours in a nitrogen atmosphere, thereby obtaining a liquid crystal polymer solution. The liquid crystal polymer and the additive were added thereto in the volume ratios shown in Table 1.

Subsequently, first, the solution was allowed to pass through a sintered fiber metal filter having a nominal pore diameter of 10 μm and allowed to pass through a sintered fiber metal filter having the same nominal pore diameter of 10 μm, thereby obtaining each polymer solution.

In a case where the additive was not dissolved in N-methylpyrrolidone, or in a case where the additive denatured at 140° C., a polymer solution was prepared without adding the additive, the mixture was allowed to pass through the above-described sintered fiber metal filter, and then the additive was added thereto and stirred.

—Production of Single-Sided Copper-Clad Laminated Plate—

The obtained polymer solutions for the layer A, for the layer B, and for the layer C were fed to a casting die equipped with a multi-manifold adapted for co-casting, and cast onto a treated surface of a copper foil (manufactured by FUKUDA METAL FOIL & POWER CO., LTD., CF-T9DA-SV-12, average thickness: 12 μm) so that the layer A was in contact with the copper foil. The polymer solution was dried at 40° C. for 4 hours and then at 120° C. for 3 hours to remove the solvent from the casting film. Further, a heat treatment was gradually performed in a nitrogen atmosphere from room temperature (25° C.) to 270° C., and then performed at the temperature for 2 hours to obtain a laminate (single-sided copper-clad laminated plate) including a copper layer and a film.

—Production of Double-Sided Copper-Clad Laminated Plate (Production Example 3 and Production Example 4)—

˜Copper-Clad Laminated Plate Precursor Step˜

A copper foil (manufactured by FUKUDA METAL FOIL & POWER CO., LTD., CF-T9DA-SV-12, average thickness: 12 μm) was placed on the obtained single-sided copper-clad laminated plate such that a treated surface of the copper foil was in contact with the film, and using a laminator (“Vacuum laminator V-130” manufactured by Nikko-Materials Co., Ltd.), lamination was performed for 1 minute under conditions of 140° C. and a laminating pressure of 0.4 MPa, thereby obtaining a double-sided copper foil laminated plate precursor.

˜Main Thermocompression Step˜

Using a thermocompression machine (“MP-SNL” manufactured by Toyo Seiki Seisaku-sho, Ltd.), the obtained copper-clad laminated plate precursor was subjected to thermocompression under conditions of 300° C. and 4.5 MPa for 60 minutes to produce a double-sided copper-clad laminated plate.

[Extrusion (Melt Film Formation)]

—Production of Resin Pellets—

Powder of the above-described polymer and the additive were mixed with each other, and the mixture was pelletized in a nitrogen atmosphere using a biaxial extruder. The obtained pellets for the layer A were dried with dry air at 80° C. and used.

—Production of Film—

The obtained pellets were supplied into a cylinder through the same supply port of the biaxial extruder having a screw diameter of 50 mm, and heated and kneaded at 340° C. to 350° C. to obtain a kneaded material. Subsequently, the kneaded material for the layer A was fed to a T-die having a multi-manifold structure, and a film-like kneaded material in a molten state was discharged and solidified on a chill roll. The obtained film was stripped from the chill roll, and stretched by tenter to adjust anisotropy (MD/TD) of elastic modulus to 2 or less, thereby obtaining a polymer film.

Further, the polymer solution for the layer B and the polymer solution for the layer C were applied to one corona-treated surface of the layer A (layer B) and the other surface (layer C) with a die coater, dried at 40° C. for 4 hours, and then dried at 120° C. for 3 hours to remove the solvent from the coating film and obtain a polymer film.

—Production of Single-Sided Copper-Clad Laminated Plate—

A copper foil (manufactured by FUKUDA METAL FOIL & POWER CO., LTD., CF-T9DA-SV-12, average thickness: 12 μm) was placed on the surface of the obtained polymer film on the layer C side such that a treated surface of the copper foil was in contact with the surface, and using a laminator (“Vacuum laminator V-130” manufactured by Nikko-Materials Co., Ltd.), lamination was performed for 1 minute under conditions of 140° C. and a laminating pressure of 0.4 MPa, thereby obtaining a single-sided copper foil laminated plate precursor.

—Production of Double-Sided Copper-Clad Laminated Plate (Production Example 5 and Production Example 6)—

The obtained polymer film was sandwiched between a pair of copper foils (manufactured by FUKUDA METAL FOIL & POWER CO., LTD., CF-T9DA-SV-12, average thickness: 12 μm) such that a treated surface of the copper foil was in contact with the film, and using a laminator (“Vacuum laminator V-130” manufactured by Nikko-Materials Co., Ltd.), lamination was performed for 1 minute under conditions of 140° C. and a laminating pressure of 0.4 MPa, thereby obtaining a double-sided copper foil laminated plate precursor.

˜Main Thermocompression Step˜

Using a thermocompression machine (“MP-SNL” manufactured by Toyo Seiki Seisaku-sho, Ltd.), the obtained copper-clad laminated plate precursor was subjected to thermocompression under conditions of 300° C. and 4.5 MPa for 60 minutes to produce a double-sided copper-clad laminated plate.

<Production of Flexible Wiring Board>

Using the single-sided copper-clad laminated plate and the double-sided copper-clad laminated plate described above, a flexible wiring board having a four-layered stripline structure with an outer-layer plane (ground layer) was produced.

[Step of Forming Wiring Base Material]

The copper foil of the above-described double-sided copper-clad laminated plate was patterned by a known photofabrication method to produce a wiring base material including three pairs of signal lines. A length of the signal line was 100 mm, and a width of the signal line was set such that characteristic impedance was 50Ω.

[Lamination Step]

Using the above-described wiring base material and a pair of the above-described single-sided copper-clad laminated plates, a laminate of single-sided copper-clad laminated plate/wiring base material/single-sided copper-clad laminated plate was formed such that the wiring base material was in contact with the film side of the single-sided copper-clad laminated plate. Using a vacuum press apparatus, the lamination was performed at a temperature shown in Table 1 to produce a flexible wiring board. As the above-described double-sided copper-clad laminated plate, those using the films of Production Examples 1 to 6 shown in Table 2 were used according to the pressing temperature.

Evaluation regarding distortion of wiring line was performed using the produced flexible wiring board. The evaluation methods were as follows. The evaluation results are shown in Table 1.

<Wiring Distortion>

The flexible wiring board was cut with a microtome, the cross section was observed with an optical microscope, and the distortion of the wiring line was evaluated based on the following evaluation standard.
A: No distortion was recognized in the signal lines and the ground line.
B: While no distortion was recognized in the signal lines, distortion was recognized in the ground line.
C: Distortion was recognized in a pair of signal lines.
D: Distortion was recognized in two pairs or three pairs of signal lines.

TABLE 1

| | Layer B (air side surface layer) | | | | | | | Layer A (core layer) | | | |
|---|---|---|---|---|---|---|---|---|---|---|---|
| | Liquid | | | | | | | Liquid | | | |
| | crystal | | | | Elastic | | | crystal | | | |
| | polymer | | Additive | | modulus | | | polymer | | Additive | |
| | | Content | | Content | (GPa) | | | | Content | | Content |
| | | (% by | | (% by | 160° | 300° | Thickness | | (% by | | (% by |
| | Type | mass ) | Type | mass) | C. | C. | (μm) | Type | mass ) | Type | mass) |
| Example 1 | LC-A | 50 | A-1 | 50 | 0.4 | 0.1 | 13 | LC-A | 100 | — | — |
| Example 2 | LC-A | 50 | A-1 | 50 | 0.4 | 0.1 | 13 | LC-A | 100 | — | — |
| Example 3 | LC-A | 50 | A-1 | 50 | 0.4 | 0.1 | 13 | LC-A | 50 | F-1 | 50 |
| Comparative | LC-A | 100 | — | — | 0.9 | 0.4 | 2 | LC-A | 100 | — | — |
| Example 1 | | | | | | | | | | | |
| Example 4 | LC-B | 20 | A-2 | 80 | 3E−05 | 2E−05 | 15 | LC-B | 50 | F-2 | 50 |
| Example 5 | LC-B | 40 | A-2 | 60 | 5E−05 | 3E−05 | 15 | LC-B | 50 | F-2 | 50 |
| Example 6 | LC-B | 20 | A-3 | 80 | 3E−05 | 2E−05 | 15 | LC-B | 50 | F-2 | 50 |
| Example 7 | LC-B | 40 | A-2 | 60 | 5E−05 | 3E−05 | 15 | LC-B | 50 | F-3 | 50 |
| Example 8 | LC-B | 40 | A-2 | 60 | 5E−05 | 3E−05 | 15 | LC-B | 50 | F-4 | 50 |
| Example 9 | LC-B | 40 | A-4 | 60 | 1E−05 | 1E−05 | 15 | LC-B | 50 | F-2 | 50 |
| Example 10 | LC-B | 40 | A-5 | 60 | 0.002 | 0.001 | 15 | LC-B | 50 | F-2 | 50 |
| Example 11 | LC-B | 40 | A-2 | 60 | 5E−05 | 3E−05 | 15 | LC-C | 100 | — | — |
| Example 12 | LC-D | 40 | A-2 | 60 | 5E−05 | 3E−05 | 15 | LC-D | 50 | F-2 | 50 |

| | | | | Layer C (copper foil side surface layer) | | | | | | |
|---|---|---|---|---|---|---|---|---|---|---|
| | Layer A (core layer) | | | Liquid | | | | | | |
| | Elastic | | | crystal | | | | Elastic | | |
| | modulus | | | polymer | | Additive | | modulus | | |
| | (GPa) | | | | Content | | Content | (GPa) | | |
| | 160° | 300° | Thickness | | (% by | | (% by | 160° | 300° | Thickness |
| | C. | C. | (μm) | Type | mass) | Type | mass) | C. | C. | (μm) |
| Example 1 | 0.9 | 0.4 | 35 | LC-A | 50 | M-1 | 50 | 0.6 | 0.2 | 2 |
| Example 2 | 0.9 | 0.4 | 35 | LC-A | 50 | M-1 | 50 | 0.6 | 0.2 | 2 |
| Example 3 | 2.3 | 1.1 | 35 | LC-A | 50 | M-1 | 50 | 0.6 | 0.2 | 2 |
| Comparative | 0.9 | 0.4 | 46 | LC-A | 100 | — | — | 0.9 | 0.4 | 2 |
| Example 1 | | | | | | | | | | |
| Example 4 | 0.8 | 0.3 | 33 | LC-B | 95 | M-2 | 5 | 0.9 | 0.4 | 2 |
| Example 5 | 0.8 | 0.3 | 33 | LC-B | 95 | M-2 | 5 | 0.9 | 0.4 | 2 |
| Example 6 | 0.8 | 0.3 | 33 | LC-B | 95 | M-2 | 5 | 0.9 | 0.4 | 2 |
| Example 7 | 2.3 | 1.1 | 33 | LC-B | 95 | M-2 | 5 | 0.9 | 0.4 | 2 |
| Example 8 | 2.4 | 1.2 | 33 | LC-B | 95 | M-2 | 5 | 0.9 | 0.4 | 2 |
| Example 9 | 0.8 | 0.3 | 33 | LC-B | 95 | M-2 | 5 | 0.9 | 0.4 | 2 |
| Example 10 | 0.8 | 0.3 | 33 | LC-B | 95 | M-2 | 5 | 0.9 | 0.4 | 2 |
| Example 11 | 0.9 | 0.4 | 46 | LC-B | 95 | M-2 | 5 | 0.9 | 0.4 | 2 |
| Example 12 | 0.8 | 0.3 | 33 | LC-D | 95 | M-2 | 5 | 0.9 | 0.4 | 2 |

| | | | | Evaluation result | | |
|---|---|---|---|---|---|---|
| | | | | Film | | |
| | | Laminate | | | Thermal | |
| | | | Pressing | Dielectric | expansion | Laminate |
| | Film | Wiring | temperature | loss | coefficient | Wiring |
| | formation | board | (° C.) | tangent | (ppm/K) | distortion |
| Example 1 | Co-casting A | Production | 300 | 0.003 | 35 | C |
| | | Example 2 | | | | |
| Example 2 | Co-casting A | Production | 160 | 0.003 | 35 | B |
| | | Example 1 | | | | |
| Example 3 | Co-casting A | Production | 300 | 0.002 | 19 | A |
| | | Example 2 | | | | |
| Comparative | Co-casting A | Production | 300 | 0.003 | 33 | D |
| Example 1 | | Example 2 | | | | |
| Example 4 | Co-casting B | Production | 160 | 0.003 | 37 | A |
| | | Example | | | | |
| Example 5 | Co-casting B | Production | 160 | 0.003 | 37 | A |
| | | Example 3 | | | | |
| Example 6 | Co-casting B | Production | 160 | 0.003 | 37 | A |
| | | Example 3 | | | | |
| Example 7 | Co-casting B | Production | 160 | 0.003 | 18 | A |
| | | Example 3 | | | | |
| Example 8 | Co-casting B | Production | 160 | 0.003 | 20 | A |
| | | Example 3 | | | | |
| Example 9 | Co-casting B | Production | 160 | 0.003 | 37 | A |
| | | Example 3 | | | | |
| Example 10 | Co-casting B | Production | 160 | 0.003 | 37 | B |
| | | Example 3 | | | | |
| Example 11 | Extrusion | Production | 160 | 0.002 | 18 | A |
| | | Example 5 | | | | |
| Example 12 | Co-casting B | Production | 160 | 0.003 | 37 | A |
| | | Example 3 | | | | |

TABLE 2

| | Layer B (air side surface layer) | | | | | | | Layer A (core layer) | | | | | | |
|---|---|---|---|---|---|---|---|---|---|---|---|---|---|---|
| | Liquid | | | | | | | Liquid | | | | | | |
| | crystal | | | | Elastic | | | crystal | | | | Elastic | | |
| | polymer | | Additive | | modulus | | | polymer | | Additive | | modulus | | |
| | | Content | | Content | (GPa) | | | | Content | | Content | (GPa) | | |
| | | (% by | | (% by | 160° | 300° | Thickness | | (% by | | (% by | 160° | 300° | Thickness |
| | Type | mass) | Type | mass) | C. | C. | (μm) | Type | mass) | Type | mass ) | C. | C. | (μm) |
| Production | LC-A | 50 | M-1 | 50 | 0.6 | 0.2 | 2 | LC-A | 100 | — | — | 0.9 | 0.4 | 46 |
| Example 1 | | | | | | | | | | | | | | |
| Production | LC-A | 50 | M-1 | 50 | 0.6 | 0.2 | 2 | LC-A | 50 | F-1 | 50 | 2.3 | 1.1 | 46 |
| Example 2 | | | | | | | | | | | | | | |
| Production | LC-B | 95 | M-2 | 5 | 0.6 | 0.2 | 2 | LC-B | 100 | — | — | 0.9 | 0.4 | 46 |
| Example 3 | | | | | | | | | | | | | | |
| Production | LC-B | 95 | M-2 | 5 | 0.6 | 0.2 | 2 | LC-B | 50 | F-1 | 50 | 2.3 | 1.1 | 46 |
| Example 4 | | | | | | | | | | | | | | |
| Production | LC-B | 95 | M-2 | 5 | 0.6 | 0.2 | 2 | LC-C | 100 | — | — | 0.9 | 0.4 | 46 |
| Example 5 | | | | | | | | | | | | | | |
| Production | LC-B | 95 | M-2 | 5 | 0.6 | 0.2 | 2 | LC-C | 100 | — | — | 0.9 | 0.4 | 46 |
| Example 6 | | | | | | | | | | | | | | |

| | Layer C (copper foil side surface layer) | | | | | | | | | |
|---|---|---|---|---|---|---|---|---|---|---|
| | Liquid | | | | | | | | Evaluation result | |
| | crystal | | | | Elastic | | | | Film | |
| | polymer | | Additive | | modulus | | | | | Thermal |
| | | Content | | Content | (GPa) | | | | Dielectric | expansion |
| | | (% by | | (% by | 160° | 300° | Thickness | Film | loss | coefficient |
| | Type | mass ) | Type | mass) | C. | C. | (μm) | formation | tangent | (ppm/K) |
| Production | LC-A | 50 | M-1 | 50 | 0.6 | 0.2 | 2 | Co-casting A | 0.003 | 33 |
| Example 1 | | | | | | | | | | |
| Production | LC-A | 50 | M-1 | 50 | 0.6 | 0.2 | 2 | Co-casting A | 0.003 | 17 |
| Example 2 | | | | | | | | | | |
| Production | LC-B | 95 | M-2 | 5 | 0.6 | 0.2 | 2 | Co-casting B | 0.003 | 33 |
| Example 3 | | | | | | | | | | |
| Production | LC-B | 95 | M-2 | 5 | 0.6 | 0.2 | 2 | Co-casting B | 0.003 | 20 |
| Example 4 | | | | | | | | | | |
| Production | LC-B | 95 | M-2 | 5 | 0.6 | 0.2 | 2 | Extrusion | 0.002 | 17 |
| Example 5 | | | | | | | | | | |
| Production | LC-B | 95 | M-2 | 5 | 0.6 | 0.2 | 2 | Extrusion | 0.002 | 17 |
| Example 6 | | | | | | | | | | |

As shown in Table 1, in Examples 1 to 12, it was found that the dielectric loss tangent was 0.01 or less, distortion of the wiring line was suppressed, and the transmission loss of the flexible wiring board was within the allowable range.

On the other hand, in Comparative Example 1, it was found that the decrease in elastic modulus of the surface at the pressing temperature was not sufficient, the distortion of the wiring line occurred, and the transmission loss of the flexible wiring board was deteriorated.

The disclosure of Japanese Patent Application No. 2021-013762 filed on Jan. 29, 2021 is incorporated in the present specification by reference.

All documents, patent applications, and technical standards described in the present specification are incorporated herein by reference to the same extent as in a case of being specifically and individually noted that individual documents, patent applications, and technical standards are incorporated by reference.

What is claimed is:

1. A polymer film comprising:
a layer A; and
a layer B on at least one surface of the layer A,
wherein the layer A contains a polymer having a dielectric loss tangent of 0.01 or less,
the layer B contains an additive, and
the layer B has an inflection point in a change in elastic modulus due to a change in temperature or a change in deformation rate, or has a reduced elastic modulus under pressurization.

2. A polymer film comprising:
a layer A; and
a layer B on at least one surface of the layer A,
wherein the layer A contains at least one polymer A selected from the group consisting of a liquid crystal polymer, a fluorine-based polymer, a polymerized substance of a compound which has a cyclic aliphatic hydrocarbon group and a group having an ethylenically unsaturated bond, a polyphenylene ether, and an aromatic polyether ketone,
the layer B contains an additive, and
the layer B has an inflection point in a change in elastic modulus due to a change in temperature or a change in deformation rate, or has a reduced elastic modulus under pressurization.

3. A polymer film comprising:
a layer A; and
a layer B on at least one surface of the layer A,
wherein the layer A contains a polymer having a dielectric loss tangent of 0.01 or less, and
the layer B contains an additive which is compatible with the polymer having a dielectric loss tangent of 0.01 or less at 25° C. and is to be phase-separable from the polymer having a dielectric loss tangent of 0.01 or less by heating.

4. A polymer film comprising:
a layer A; and
a layer B on at least one surface of the layer A,
wherein the layer A contains at least one polymer A selected from the group consisting of a liquid crystal polymer, a fluorine-based polymer, a polymerized substance of a compound which has a cyclic aliphatic hydrocarbon group and a group having an ethylenically unsaturated bond, a polyphenylene ether, and an aromatic polyether ketone, and
the layer B contains an additive which is compatible with the polymer A at 25° C. and is to be phase-separable from the polymer A by heating.

5. A polymer film comprising:
a layer A; and
a layer B on at least one surface of the layer A,
wherein the layer A contains a polymer having a dielectric loss tangent of 0.01 or less, and
the layer B contains an additive which is phase-separable from the polymer having a dielectric loss tangent of 0.01 or less at 25° C. and is to be compatible with the polymer having a dielectric loss tangent of 0.01 or less by heating.

6. A polymer film comprising:
a layer A; and
a layer B on at least one surface of the layer A,
wherein the layer A contains at least one polymer A selected from the group consisting of a liquid crystal polymer, a fluorine-based polymer, a polymerized substance of a compound which has a cyclic aliphatic hydrocarbon group and a group having an ethylenically unsaturated bond, a polyphenylene ether, and an aromatic polyether ketone, and
the layer B contains an additive which is phase-separable from the polymer A at 25° C. and is to be compatible with the polymer A by heating.

7. The polymer film according to claim 1,
wherein the layer B contains the polymer having a dielectric loss tangent of 0.01 or less.

8. The polymer film according to claim 1,
wherein an elastic modulus of the layer B at 160° C. is 1 GPa or less.

9. The polymer film according to claim 1,
wherein a melting point of the additive is 130° C. to 180° C.

10. The polymer film according to claim 1,
wherein an elastic modulus of the layer B at 300° C. is 1 GPa or less.

11. The polymer film according to claim 1,
wherein a melting point of the additive is 270° C. to 320° C.

12. The polymer film according to claim 1,
wherein an elastic modulus of the layer B at 160° C. is reduced under pressurization at 5 MPa.

13. The polymer film according to claim 2,
wherein the additive is an additive which is compatible with the polymer having a dielectric loss tangent of 0.01 or less or the polymer A, and is to be phase-separable from the polymer having a dielectric loss tangent of 0.01 or less or the polymer A under pressurization at 5 MPa.

14. The polymer film according to claim 2,
wherein the additive is an additive which is phase-separable from the polymer having a dielectric loss tangent of 0.01 or less or the polymer A, and is to be compatible in the polymer having a dielectric loss tangent of 0.01 or less or the polymer A under pressurization at 5 MPa.

15. The polymer film according to claim 2,
wherein the polymer having a dielectric loss tangent of 0.01 or less or the polymer A is a liquid crystal polymer.

16. The polymer film according to claim 2,
wherein a melting point Tm or a 5%-by-mass-loss temperature Td of the polymer having a dielectric loss tangent of 0.01 or less or the polymer A is 200° C. or higher.

17. The polymer film according to claim 2,
wherein the polymer having a dielectric loss tangent of 0.01 or less or the polymer A is a liquid crystal polymer having a structural unit represented by any of Formulae (1) to (3),
—O—Ar¹—CO— Formula (1)
—CO—Ar²—CO— Formula (2)
—X—Ar³—Y— Formula (3)
in Formulae (1) to (3), Ar¹ represents a phenylene group, a naphthylene group, or a biphenylylene group, Ar² and Ar³ each independently represent a phenylene group, a naphthylene group, a biphenylylene group, or a group represented by Formula (4), X and Y each independently represent an oxygen atom or an imino group, and hydrogen atoms in Ar¹ to Ar³ may be each independently substituted with a halogen atom, an alkyl group, or an aryl group,
—Ar⁴—Z—Ar⁵— Formula (4)
in Formula (4), Ar⁴ and Ar⁵ each independently represent a phenylene group or a naphthylene group, and Z represents an oxygen atom, a sulfur atom, a carbonyl group, a sulfonyl group, or an alkylene group.

18. The polymer film according to claim 1, further comprising:
a layer C,
wherein the layer B, the layer A, and the layer C are provided in this order, and
the layer C contains the additive.

19. A laminate comprising:
the polymer film according to claim 1; and
a copper layer or a copper wire disposed on at least one surface of the polymer film.

20. The laminate according to claim 19,
wherein a peel strength between the polymer film and the copper layer is 0.5 kN/m or more.

21. A method for manufacturing a laminate, comprising:
a lamination step of laminating the polymer film according to claim 1 with a copper layer or a copper wire at a temperature of (a melting point of the additive−30° C.) or higher and (the melting point+30° C.) or lower.

22. A method for manufacturing a laminate, comprising:
a lamination step of laminating the polymer film according to claim 1 with a copper layer or a copper wire at a pressure of (a pressure at which an elastic modulus of the layer B changes−5 MPa) or more and (the pressure at which the elastic modulus of the layer B changes+10 MPa) or less.

23. A method for manufacturing a laminate, comprising:
a step of laminating the polymer film according to claim 1 with a copper layer or a copper wire at a temperature of (a melting point of the additive−30° C.) or higher and (the melting point+30° C.) or lower and at a pressure of (a pressure at which an elastic modulus of the layer B changes−5 MPa) or more and (the pressure at which the elastic modulus of the layer B changes+10 MPa) or less.
